(19) United States
(12) Patent Application Publication
(10) Pub. No.: US 2015/0376813 A1
(43) Pub. Date: Dec. 31, 2015

(54) METHOD FOR PRODUCING HEXAGONAL SINGLE CRYSTAL, METHOD FOR PRODUCING HEXAGONAL SINGLE CRYSTAL WAFER, HEXAGONAL SINGLE CRYSTAL WAFER, AND HEXAGONAL SINGLE CRYSTAL ELEMENT

(71) Applicant: CENTRAL RESEARCH INSTITUTE OF ELECTRIC POWER INDUSTRY, Chiyoda-ku, Tokyo (JP)

(72) Inventors: Hidekazu TSUCHIDA, Kanagawa (JP); Isaho KAMATA, Kanagawa (JP); Norihiro HOSHINO, Kanagawa (JP)

(73) Assignee: CENTRAL RESEARCH INSTITUTE OF ELECTRIC POWER INDUSTRY, Chiyoda-ku, TOkyo (JP)

(21) Appl. No.: 14/765,092

(22) PCT Filed: Jan. 31, 2014
(86) PCT No.: PCT/JP2014/052317

§ 371 Date: Jul. 31, 2015

(30) Foreign Application Priority Data
Jan. 31, 2013 (JP) 2013-017602
May 14, 2013 (JP) 2013-102573

(51) Int. Cl. C30B 19/12; C30B 29/36; C30B 19/04; C30B 23/02; C30B 25/20

(52) U.S. Cl. CPC C30B 19/12; C30B 23/025; C30B 25/20; C30B 19/04; C30B 29/36

(57) ABSTRACT

When growing a hexagonal single crystal, an off angle is set, in a first direction [11-20] with respect to a basal plane {0001} serving as a main crystal growth plane, in a hexagonal single crystal for use as a foundation in performing crystal growth; and a cross-sectional shape which is decreased in crystal thickness in a stair-step manner from a reference line AA′ parallel to the first direction [11-20] toward second directions [−1100], [1-100] on both sides of the reference line and orthogonal to the first direction [11-20]. Dislocations threading in a c-axis direction, contained in the hexagonal single crystal, are converted into defects inclined ≧40° from the c-axis direction toward the basal plane during crystal growth, and the direction of propagation of the defects is controlled to a direction between a direction [−1-120] opposite to the first direction [11-20] and the second directions [−1100], [1-100], to discharge defects.

### TECHNICAL FIELD

This invention relates to a method for producing a hexagonal single crystal, a method for producing a hexagonal single crystal wafer, a hexagonal single crystal wafer, and a hexagonal single crystal element. This invention is useful when applied in discharging a crystal defect out of the crystal, while utilizing a change in the direction of propagation of the crystal defect, to obtain a substrate of a large diameter, particularly, a silicon carbide single crystal substrate of a large diameter.

### BACKGROUND ART

Silicon carbide (SiC) is a semiconductor having excellent physical property values including a band gap about 3 times that of Si, a saturated drift velocity about 2 times that of Si, and a dielectric breakdown electric field strength about 10 times that of Si, and also having a high thermal conductivity. Thus, it is expected as a material which realizes a next-generation, high voltage, low loss semiconductor element showing performance greatly surpassing that of the Si single crystal semiconductor now in use.

Currently, some methods are available for the production of silicon carbide single crystals now on the market, and sublimation is often used as the main method.

With the sublimation method, it is usual practice to place a silicon carbide powder as a material in a crucible, and install a silicon carbide seed crystal on an upper surface of the inside of the crucible in a manner face to face with the silicon carbide powder. At this time, the crucible is heated to a temperature of the order of 2200 to 2400° C. to sublimate the silicon carbide powder. The sublimated silicon carbide powder is recrystallized on the opposing silicon carbide seed crystal, and a new silicon carbide single crystal is grown on the seed crystal.

As the method for producing a silicon carbide single crystal, another manufacturing method called the HTCVD process (high temperature chemical vapor deposition process) has been reported which obtains a new silicon carbide single crystal on a seed crystal, as in the sublimation method, with the use of an Si-containing gas such as SiH₄, and a C-containing gas such as C₂H₈ or C₂H₂, as materials. Also has been reported a manufacturing method called the solution growth method which obtains a new silicon carbide single crystal on a seed crystal by use of a solution containing C in liquid Si as a material.

After the silicon carbide single crystal is obtained as a columnar bulk single crystal by any of the above-mentioned methods, it is usually sliced to a thickness of the order of 300 to 500 μm to produce a silicon carbide single crystal substrate. When a semiconductor element is to be produced using this silicon carbide single crystal substrate, it is often the case that a single crystal layer having a required film thickness and a required carrier concentration based on requirement specifications such as the withstand voltage of the semiconductor element is epitaxially grown from the surface of the substrate.

The silicon carbide single crystal substrate is produced by the method as described above, but under ordinary pressure, it has no liquid phase, and its sublimation temperature is extremely high. For such reasons, it is difficult to carry out high quality crystal growth free from a crystal defect such as dislocation or stacking fault. With the silicon carbide single crystal, therefore, a manufacturing technology for a single crystal free from dislocations and having a large diameter, such as one commercialized in Si single crystal growth, has not been actualized.

In the silicon carbide single crystal substrates now on the market, there exist threading screw dislocations propagating in the c-axis direction at a density of the order of 10² cm⁻² to 10³ cm⁻², threading edge dislocations propagating in the c-axis direction at a density of the order of 10² cm⁻² to 10⁴ cm⁻², and dislocations propagating in a direction perpendicular to the c-axis at a density of the order of 10² cm⁻² to 10⁴ cm⁻² (basal plane dislocations). The threading screw dislocations and the threading edge dislocations are collectively called the threading dislocations. The densities of these dislocations differ greatly depending on the quality of the substrate.

These dislocations inherent in the silicon carbide single crystal substrate propagate through the epitaxial film during growth of the epitaxial film on the substrate. At this time, some of the dislocations are known to have the possibility of changing in the direction of extension (direction of propagation) during propagation through the epitaxial film. It is also known that when the epitaxial film is grown on the substrate, new dislocation loops or stacking faults (8H type, 3C type, etc.) occur.

In the epitaxial film, therefore, the dislocations or stacking faults introduced during epitaxial growth are contained, in addition to the dislocations or stacking faults propagating from the substrate. These dislocations or stacking faults lower or reduce the withstand voltage or reliability of a semiconductor element formed using the epitaxial film.

Recently, technologies for decreasing the dislocation density in the substrate or the density of dislocations occurring during epitaxial growth have been under development. A plurality of reports have been issued on techniques for reducing threading screw dislocations in the growth of a silicon carbide single crystal (Patent Documents 1 to 5, Non-Patent Documents 1 to 4).

Patent Document 1 shows a method for decreasing the density of threading dislocations in a silicon carbide crystal growth region by rendering a prism plane orthogonal to the basal plane {0001} a crystal growth plane, and setting the direction of crystal growth and the direction of propagation of threading dislocations to be nearly perpendicular to each other.

Patent Document 2 shows a technique which obtains a silicon carbide single crystal with a decreased threading dislocation density by alternately repeating a silicon carbide crystal growth step, with the {11-20} plane and the {1-100} plane orthogonal to the basal plane {0001} being crystal growth planes, to decrease the density of threading dislocations in a single crystal, cutting out the resulting single crystal, and performing crystal growth, with the basal plane {0001} serving as a crystal growth plane.

Non-Patent Document 1 shows that threading dislocations can be reduced by performing silicon carbide crystal growth, with a (03-38) plane inclined at 54.74° with respect to the basal plane {0001} being set as a crystal growth plane. Non-Patent Document 1 also reports that in vapor phase epitaxial growth onto a 4H-SiC(03-38) substrate, with the (03-38) plane being used as the crystal growth plane, threading dislocations contained in the substrate are converted into defects within the basal plane during epitaxial growth, whereby the density of the threading dislocations is decreased.

Non-Patent Document 2 reports that in 4H-SiC sublimation-based crystal growth using a silicon carbide single crystal substrate as a seed crystal and setting the basal plane {0001} as a crystal growth plane, threading dislocations are converted into defects in the basal plane in a region where the direction of crystal growth is inclined with respect to the c-axis, with the result that the density of the threading dislocations in the region is decreased.

These reports indicate that when, in silicon carbide crystal growth, the crystal growth plane is greatly inclined (e.g., 50° or more) from the basal plane {0001}, threading dislocations within the substrate or in the seed crystal can be decreased.

Non-Patent Documents 3 and 4, on the other hand, report that in silicon carbide epitaxial growth on a crystal growth plane having an off angle (an angle of inclination of the basal plane) of 0 to 8° from the basal plane {0001}, threading dislocations within a substrate propagate as such into an epitaxial film.

A density, at which extended defects in the basal plane {0001} present in a substrate or seed crystal appear on the surface, geometrically decreases as the off angle from the basal plane {0001} becomes small. In order to decrease the density of the extended defects in the basal plane {0001} present in the substrate or seed crystal, therefore, it is advantageous to make the off angle as small as possible.

Based on the above findings, in order to decrease the threading dislocations present in the substrate or seed crystal, it is necessary to perform silicon carbide crystal growth on the crystal growth plane having a large off angle from the basal plane {0001}. In order to decrease the extended defects in the basal plane which are present in the substrate or seed crystal, by contrast, it is necessary to perform silicon carbide crystal growth on the crystal growth plane having a small off angle from the basal plane {0001}. To fulfill both of these requirements at the same time has posed a challenge.

It has also been reported to impart an uneven shape to a substrate beforehand in silicon carbide vapor phase epitaxial growth on the substrate, thereby reducing crystal defects. Patent Document 3 reports that a striped uneven shape having a side wall oriented in a direction perpendicular to or non-parallel to an off-cut direction (direction in which the basal plane is tilted, with the off angle being set) is provided for the surface of a silicon carbide single crystal substrate, whereby the ratio at which basal plane dislocations within the substrate are converted into defects of other type can be increased.

Patent Document 4 shows that for the surface of a silicon carbide single crystal substrate, crystal growth on the substrate surface having a striped uneven shape in a direction parallel to the direction of inclination from the basal plane {0001}, and crystal growth on the substrate surface having striped irregularities oriented perpendicularly to the above direction are alternately carried out, whereby the density of crystal defects within the substrate is decreased.

Further, Patent Document 5 reports that epitaxial growth on a substrate surface having an off angle from a basal plane {0001} is performed, then a striped uneven shape nearly parallel to the direction of inclination from the basal plane {0001} is provided, and second epitaxial growth is performed, whereby the density of defects within the substrate is decreased.

According to the methods of Patent Documents 3 to 5, a certain type of crystal defect can be converted into other type of crystal defects, or a region at a low density of the certain type of crystal defects can be secured, by performing growth in a direction perpendicular to the striped irregular-shaped side wall provided in the substrate. However, these advantages are not sufficient to achieve control over the direction of propagation of crystal defects in the entire crystal, and the effect of decreasing the defect density is low. Thus, a technology for discharging crystal defects out of the crystal, while utilizing the conversion of the crystal defects, has been desired.

Non-Patent Document 5, on the other hand, shows that in SiC crystal growth, threading dislocations contained in a substrate are deflected toward the basal plane by macrosteps with a large step height.

As indicated in Non-Patent Document 5, however, even when the threading dislocations are once converted into basal plane defects by macrosteps having a great step height, they are converted again into threading dislocations in the presence of the opposing steps. Thus, such an advantage is insufficient to achieve control over the direction of propagation of crystal defects, and the effect of decreasing the defect density is low. Hence, a technology for discharging crystal defects out of the crystal, while utilizing the change in the propagation direction of the crystal defects by macrosteps with a great step height, has been desired.

Patent Document 6, on the other hand, reports on a method which comprises converting threading dislocations into defects in a first direction along a basal plane {0001}, and controlling the direction of propagation of the defects to a second direction intersecting the first direction and extending along the basal plane {0001}, thereby structurally converting the threading dislocations contained in a single crystal substrate into the defects in the base plane, for discharge of the defects to the outside of the crystal, to decrease the defect density in the substrate.

With the method of Patent Document 6, however, as the diameter of the substrate increases, it becomes impossible to secure a sufficient angle of inclination, from the second direction, of a striped uneven-shaped side wall provided in the substrate. This results in the difficulty of controlling the basal plane defects in the large-diameter substrate to the second direction. Thus, a technology for reliably discharging crystal defects out of the crystal, while utilizing a change in the propagation direction of the crystal defects, has been desired of a large-diameter substrate as well.

Non-Patent Documents 6 and 7, on the other hand, report that in SiC crystal growth by the solution growth method or the MSE methods, threading dislocations contained in a substrate are converted with a high probability into basal plane defects heading toward a step flow direction.

However, it is difficult now to grow a large-diameter crystal 4 inches or more in diameter with high quality by the MSE method or the solution growth method. Furthermore, the conversion of threading dislocations in the solution growth method or the MSE method into basal plane defects is limited to the (0001)Si plane, and the (000-1)C plane used in performing ingot growth has been found to pose difficulty in converting threading dislocations into basal plane defects not only in the solution growth method, but also in the MSE method. Hence, there has been a desire for a technology which can be applied to a sublimation process or a high temperature gas method capable of growing a large-diameter crystal having a diameter of 4 inches or more, and can deflect threading dislocations contained in a substrate toward the basal plane with a high probability even in crystal growth on the (000-1)C plane, thus discharging the crystal defects outside the crystal.

### PRIOR ART DOCUMENTS

### Patent Documents

[Patent Document 1] JP-A-Hei-5-262599
[Patent Document 2] JP-A-2006-1836
[Patent Document 3] JP-T-2007-529900
[Patent Document 4] JP-A-2005-350278
[Patent Document 5] JP-A-2008-94700
[Patent Document 6] JP-A-2011-251868

### Non-Patent Documents

[Non-Patent Document 1] Materials Science Forum, Vols. 433-436, 2003, pp. 197-200
[Non-Patent Document 2] Materials Science Forum, Vols. 57-460, 2004, pp. 99-102
[Non-Patent Document 3] Journal of Crystal Growth, Vol. 260, 2004, pp. 209-216
[Non-Patent Document 4] Journal of Crystal Growth, Vol. 269, 2004, pp. 367-376
[Non-Patent Document 5] Materials Science Forum, Vols. 717-720, 2012, pp. 327-330
[Non-Patent Document 6] Materials Science Forum, Vols. 717-720, 2012, pp. 351-354
[Non-Patent Document 7] Materials Science Forum, Vol. 725, 2012, pp. 31-34

### SUMMARY OF THE INVENTION

### Problems to be Solved by the Invention

The present invention has been accomplished in the light of the above-mentioned circumstances. It is an object of the invention to provide a method for producing a hexagonal single crystal which, in newly forming a hexagonal single crystal layer on a hexagonal single crystal, as a foundation, comprising a hexagonal single crystal substrate such as silicon carbide or an epitaxial film-equipped hexagonal single crystal substrate, can deflect threading dislocations contained in the hexagonal single crystal toward the basal plane, and can discharge the threading dislocations out of the crystal; a method for producing a hexagonal single crystal wafer; a hexagonal single crystal wafer; and a hexagonal single crystal element.

### Means for Solving the Problems

A first aspect of the present invention, aimed at attaining the above object, is a method for producing a hexagonal single crystal, comprising a process of growing a hexagonal single crystal,

the process comprising:

setting an off angle, in a first direction with respect to a basal plane serving as a main crystal growth plane, in the hexagonal single crystal for use as a foundation in performing crystal growth; and

forming a cross-sectional shape which is decreased in crystal thickness in a stair-step manner from a single reference line along the first direction toward second directions on both sides of the reference line and orthogonal to the first direction,

thereby converting dislocations threading in a c-axis direction, which are contained in the hexagonal single crystal, into defects inclined by 40° or more from the c-axis direction toward the basal plane during crystal growth, and controlling the direction of propagation of the defects to a direction between a direction opposite to the first direction and the second directions, to discharge the defects out of the crystal.

According to the present aspect, the cross-sectional shape is formed which is decreased in crystal thickness in a stair-step manner toward the second directions on both sides perpendicular to the first direction. In the process of forming a new hexagonal single crystal layer on the original hexagonal single crystal, therefore, the threading dislocations contained in the original single crystal can be deflected toward the basal plane to discharge the basal plane defects out of the crystal.

A second aspect of the present invention is the method for producing a hexagonal single crystal according to the first aspect, wherein

the main crystal growth plane the an off angle of 10° or less from the basal plane, and deflects and propagates the threading dislocations in a direction within 45° from the second directions on both sides toward the direction opposite to the first direction, thereby discharging the dislocations out of the crystal.

According to the present aspect, the off angle can be optimized. As a result, deterioration of the quality of a hexagonal single crystal layer in the process of growing a new hexagonal single crystal layer can be minimized. Incidentally, as the off angle increases, the crystal thickness necessary for discharging the dislocations increases, while as the off angle decreases, the frequency of occurrence of new crystal defects increases.

A third aspect of the present invention is the method for producing a hexagonal single crystal according to the first or second aspect, further comprising:

setting the angle of steps at 55° or more from the basal plane in forming the cross-sectional shape which is decreased in crystal thickness in a stair-step manner from a center line along the first direction toward the second directions.

According to the present aspect, the angle of the steps can be optimized. Incidentally, if, in the cross-sectional shape of the present embodiment, the angle of the steps is less than 54.7° corresponding to the angle between the basal plane and the (03-38) plane, the probability of deflection of the threading dislocations toward the basal plane when the patterned steps intersect the threading dislocations decreases, and the proportion of the threading dislocations propagating in the c-axis direction and remaining in the crystal increases. If the angle of the steps is less than 45° from the basal plane, moreover, many of the threading dislocations TDs propagate in the c-axis direction and remain in the crystal.

A fourth aspect of the present invention is the method for producing a hexagonal single crystal according to any one of the first to third aspects, wherein

the first direction is within ±10° from a <11-20> direction, and the second directions are within ±10° from a <1-100> direction and <−1100> direction orthogonal to the first direction.

According to the present aspect, when the stair-like cross-sectional shape is formed, deterioration of the quality of a hexagonal single crystal layer in the process of growing a new hexagonal single crystal layer can be minimized.

A fifth aspect of the present invention is the method for producing a hexagonal single crystal according to any one of the first to fourth aspects, further comprising:

setting the center line along the first direction to be in a range of ±10 mm from the center of the hexagonal single crystal serving as the foundation in forming the cross-sectional shape which is decreased in crystal thickness in a stair-step manner toward the second directions.

According to the present aspect, when the stair-like cross-sectional shape is formed, the longest distance until the threading dislocations are discharged to the end of the wafer upon their deflection toward the basal plane can be decreased.

A sixth aspect of the present invention is the method for producing a hexagonal single crystal according to any one of the first to fifth aspects, further comprising:

setting the height of steps at 2 μm or more, but 1 mm or less, the spacing between the steps at 10 μm or more, but 10 mm or less, and the number of the steps at 5 or more, in forming the cross-sectional shape which is decreased in crystal thickness in a stair-step manner from the center line along the first direction toward the second directions orthogonal to the first direction.

According to the present aspect, when the patterned steps intersect the threading dislocations, the probability of the threading dislocations being deflected toward the basal plane can be increased. Incidentally, if the height of the steps is less than 2 μm, the probability of deflection of the threading dislocations toward the basal plane when the patterned steps intersect the threading dislocations decreases, and the proportion of the threading dislocations propagating in the c-axis direction and remaining in the crystal increases. If the spacing between the steps exceeds 10 mm, the average distance until the patterned steps intersect the threading dislocations increases, and the shape of the patterned steps cannot be retained. Thus, the probability of deflection of the threading dislocations toward the basal plane decreases, and the proportion of the threading dislocations propagating in the c-axis direction and remaining in the crystal increases. By setting the height of the steps at 2 μm or more, but 1 mm or less, and the spacing between the steps at 10 μm or more, but 10 mm or less, the thickness of the original hexagonal single crystal serving as the foundation for performing crystal growth can be rendered as small as possible. The number of the steps depends on the diameter of the single crystal, but is normally required to be 5 or more.

A seventh aspect of the present invention is a method for producing a hexagonal single crystal, comprising a process of growing a hexagonal single crystal,

the process comprising:

setting an off angle, in a first direction with respect to a basal plane serving as a main crystal growth plane, in the hexagonal single crystal for use as a foundation in performing crystal growth; and

forming a cross-sectional shape which is decreased in crystal thickness in a stair-step manner from a plurality of reference lines along the first direction toward second directions on both sides of the reference lines and orthogonal to the first direction,

thereby converting dislocations threading in a c-axis direction, which are contained in the hexagonal single crystal, into defects inclined by 40° or more from the c-axis direction toward the basal plane during crystal growth, and controlling the direction of propagation of the defects to a direction between a direction opposite to the first direction and the second directions, to discharge the defects out of the crystal.

According to the present aspect, the plurality of reference lines are provided. In the process of forming a new hexagonal single crystal layer on the original hexagonal single crystal, therefore, the threading dislocations contained in the original single crystal can be deflected toward the basal plane, with a higher probability, to discharge the threading dislocations out of the crystal more satisfactorily.

An eighth aspect of the present invention is the method for producing a hexagonal single crystal according to the seventh aspect, wherein

the main crystal growth plane has the off angle of 10° or less from the basal plane, and deflects and propagates the threading dislocations in a direction within 45° from the second directions on both sides toward the direction opposite to the first direction, thereby discharging the dislocations out of the crystal or near a line intermediate between the two adjacent reference lines along the first direction.

According to the present aspect, the same actions and effects as those of the second aspect are obtained. That is, the off angle can be optimized in the seventh aspect. As a result, deterioration of the quality of a hexagonal single crystal layer in the process of growing a new hexagonal single crystal layer can be minimized.

A ninth aspect of the present invention is the method for producing a hexagonal single crystal according to the seventh or eighth aspect, further comprising:

setting the angle of steps at 45° or more from the basal plane in forming the cross-sectional shape which is decreased in crystal thickness in a stair-step manner from the center line along the first direction toward the second directions orthogonal to the first direction.

According to the present aspect, the same actions and effects as those of the third aspect are obtained. That is, the angle of the steps can be optimized in the seventh aspect.

A tenth aspect of the present invention is the method for producing a hexagonal single crystal according to any one of the seventh to ninth aspects, wherein

the first direction is within ±10° from a <11-20> direction, and the second directions are within ±10° from a <1-100> direction and <−1100> direction orthogonal to the first direction.

According to the present aspect, the same actions and effects as those of the four aspect are obtained. That is, when the stair-like cross-sectional shape is formed in the seventh aspect, deterioration of the quality of a hexagonal single crystal layer in the process of growing a new hexagonal single crystal layer can be minimized.

An eleventh aspect of the present invention is the method for producing a hexagonal single crystal according to any one of the seventh to tenth aspects, further comprising:

setting one of the intermediate lines between the two adjacent parallel reference lines to be in a range of ±10 mm from the center of the single crystal in forming the cross-sectional shape which is decreased in crystal thickness in a stair-step manner from the plurality of reference lines along the first direction toward the second directions.

According to the present aspect, the same actions and effects as those of the fifth aspect are obtained. That is, when the stair-like cross-sectional shape is formed in the seventh aspect, deterioration of the quality of a hexagonal single crystal layer in the process of growing a new hexagonal single crystal layer can be minimized.

A twelfth aspect of the present invention is the method for producing a hexagonal single crystal according to any one of the seventh to eleventh aspects, further comprising:

setting the height of steps at 2 μm or more, but 1 mm or less, the spacing between the steps at 10 μm or more, but 10 mm or less, and the number of the steps at 5 or more, in forming the cross-sectional shape which is decreased in crystal thickness in a stair-step manner from the plurality of reference lines along the first direction toward the second directions.

According to the present aspect, the same actions and effects as those in the sixth aspect are obtained. That is, when the patterned steps intersect the threading dislocations, the probability of the threading dislocations being deflected toward the basal plane can be increased. Moreover, the height of the steps, the spacing between the steps, and the number of the steps can be rendered appropriate.

A thirteenth aspect of the present invention is a method for producing a hexagonal single crystal, comprising a process of growing a hexagonal single crystal,

the process comprising:

setting an off angle, in a first direction with respect to a basal plane serving as a main crystal growth plane, in the hexagonal single crystal for use as a foundation in performing crystal growth; and

forming a cross-sectional shape which is decreased in crystal thickness in a stair-step manner from a single reference line or a plurality of reference lines orthogonal to the first direction toward the first direction and a direction opposite to the first direction,

thereby converting dislocations threading in a c-axis direction, which are contained in the original hexagonal single crystal, into defects inclined by 40° or more from the c-axis direction toward the basal plane during crystal growth, and controlling the direction of propagation of the defects to the first direction and the direction opposite to the first direction, to discharge the defects out of the crystal and near a line intermediate between the adjacent reference lines.

The present aspect concerns the stair-like cross-sectional shape along the first direction and second directions. In this case as well, as in the first aspect (the case of the single reference line) or the seventh aspect (the case of the plurality of reference lines), in the process of forming a new hexagonal single crystal layer on the original hexagonal single crystal, the threading dislocations contained in the original single crystal can be satisfactorily deflected toward the basal plane, whereby the threading dislocations can be discharged satisfactorily out of the crystal.

A fourteenth aspect of the present invention is the method for producing a hexagonal single crystal according to the thirteenth aspect, wherein

the main crystal growth plane has the off angle of 10° or less from the basal plane, and deflects and propagates the threading dislocations in a direction within 45° toward the first direction and the direction opposite to the first direction, thereby discharging the threading dislocations out of the crystal or near the intermediate line between the two adjacent reference lines.

According to the present aspect, the same actions and effects as those of the second and eighth aspects are obtained. That is, the off angle can be optimized in the thirteenth aspect. As a result, deterioration of the quality of a hexagonal single crystal layer in the process of growing a new hexagonal single crystal layer can be minimized.

A fifteenth aspect of the present invention is the method for producing a hexagonal single crystal according to the thirteenth or fourteenth aspect, further comprising:

setting the angle of steps at 45° or more from the basal plane in forming the cross-sectional shape which is decreased in crystal thickness in a stair-step manner from the single reference line or the plurality of reference lines orthogonal to the first direction toward the first direction and the direction opposite to the first direction.

According to the present aspect, the same actions and effects as those of the third and ninth aspects are obtained. That is, the angle of the steps can be optimized in the thirteenth aspect.

A sixteenth aspect of the present invention is the method for producing a hexagonal single crystal according to the thirteenth or fourteenth aspect, wherein

the first direction is within ±10° from a <11-20> direction, or within ±10° from a <1-100> direction.

According to the present aspect, the same actions and effects as those of the fourth and tenth aspects are obtained. That is, when the stair-like cross-sectional shape is formed in the thirteenth aspect, deterioration of the quality of a hexagonal single crystal layer in the process of growing a new hexagonal single crystal layer can be minimized.

A seventeenth aspect of the present invention is the method for producing a hexagonal single crystal according to any one of the thirteenth to sixteenth aspects, further comprising:

setting the reference line to be in a range of ±10 mm from the center of the single crystal in forming the cross-sectional shape which is decreased in crystal thickness in a stair-step manner from the single reference line orthogonal to the first direction toward the first direction and the direction opposite to the first direction.

According to the present aspect, the same actions and effects as those of the fifth aspect are obtained. That is, when the stair-like cross-sectional shape is formed in the thirteenth aspect and in the presence of the single reference line, deterioration of the quality of a hexagonal single crystal layer in the process of growing a new hexagonal single crystal layer can be minimized.

An eighteenth aspect of the present invention is the method for producing a hexagonal single crystal according to any one of the thirteenth to sixteenth aspects, further comprising:

setting one of the intermediate lines between the two adjacent reference lines to be in a range of ±10 mm from the center of the single crystal in forming the cross-sectional shape which is decreased in crystal thickness in a stair-step manner from the plurality of reference lines orthogonal to the first direction toward the first direction and the direction opposite to the first direction.

According to the present aspect, the same actions and effects as those of the eleventh aspect are obtained. That is, when the stair-like cross-sectional shape is formed in the thirteenth aspect and in the presence of the plurality of reference lines, deterioration of the quality of a hexagonal single crystal layer in the process of growing a new hexagonal single crystal layer can be minimized.

A nineteenth aspect of the present invention is the method for producing a hexagonal single crystal according to any one of the thirteenth to eighteenth aspects, further comprising:

setting the height of steps at 2 μm or more, but 1 mm or less, the spacing between the steps at 10 μm or more, but 10 mm or less, and the number of the steps at 5 or more, in forming the cross-sectional shape which is decreased in crystal thickness in a stair-step manner from the single reference line or the plurality of reference lines orthogonal to the first direction toward the first direction and the direction opposite to the first direction.

According to the present aspect, the same actions and effects as those in the sixth and twelfth aspects are obtained. That is, when the patterned steps intersect the threading dislocations in the thirteenth aspect, the probability of the threading dislocations being deflected toward the basal plane can be increased. Moreover, the height of the steps, the spacing between the steps, and the number of the steps can be rendered appropriate.

A twentieth aspect of the present invention is a method for producing a hexagonal single crystal, comprising a process of growing a hexagonal single crystal,

the process comprising:

setting an off angle, in a first direction with respect to a basal plane serving as a main crystal growth plane, in the hexagonal single crystal for use as a foundation in performing crystal growth; and

forming a cross-sectional shape which is decreased in crystal thickness in a stair-step manner toward second directions having an angle of 30°±15° from a direction opposite to the first direction,

thereby converting dislocations threading in a c-axis direction, which are contained in the original hexagonal single crystal, into defects inclined by 40° or more from the c-axis direction toward the basal plane during crystal growth, and controlling the direction of propagation of the defects to a direction between the direction opposite to the first direction and the second directions, to discharge the defects out of the crystal.

The present aspect forms the cross-sectional shape which is decreased in crystal thickness in a stair-step manner toward second directions having an angle of 30°±15° from a direction opposite to the first direction. As in the first aspect, therefore, in the process of forming a new hexagonal single crystal layer on the original hexagonal single crystal, the threading dislocations contained in the original single crystal can be deflected toward the basal plane, whereby the basal plane defects can be discharged outside the crystal.

A twenty-first aspect of the present invention is the method for producing a hexagonal single crystal according to the twentieth aspect, wherein

the main crystal growth plane has the off angle of 10° or less from the basal plane, and deflects the threading dislocations in a direction within ±45° toward the first direction, thereby discharging the dislocations out of the crystal.

According to the present aspect, the same actions and effects as those of the second, eighth and fourteenth aspects are obtained. That is, the off angle can be optimized in the twentieth aspect. As a result, deterioration of the quality of a hexagonal single crystal layer in the process of growing a new hexagonal single crystal layer can be reduced to a minimum.

A twenty-second aspect of the present invention is the method for producing a hexagonal single crystal according to the twentieth or twenty-first aspect, further comprising:

setting the angle of steps at 45° or more from the basal plane in forming the cross-sectional shape which is decreased in crystal thickness in a stair-step manner toward the second directions having the angle of 30°±15° from the direction opposite to the first direction.

According to the present aspect, the same actions and effects as those of the third, ninth and fifteenth aspects are obtained. That is, the angle of the steps can be optimized in the twentieth aspect.

A twenty-third aspect of the present invention is the method for producing a hexagonal single crystal according to the twentieth or twenty-first aspect, wherein

the first direction is within ±10° from a <11-20> direction, or within ±10° from a <1-100> direction.

According to the present aspect, the same actions and effects as those of the fourth, tenth and sixteenth aspects are obtained. That is, when the stair-like cross-sectional shape is formed in the twentieth aspect, deterioration of the quality of a hexagonal single crystal layer in the process of growing a new hexagonal single crystal layer can be reduced to a minimum.

A twenty-fourth aspect of the present invention is the method for producing a hexagonal single crystal according to any one of the twentieth to twenty-third aspects, further comprising:

setting a region, where the crystal thickness becomes maximal, in a range of 10 mm or less from an end of the single crystal in forming the cross-sectional shape which is decreased in crystal thickness in a stair-step manner toward the second directions having the angle of 30°±15° from the direction opposite to the first direction.

According to the present aspect, the same actions and effects as those of the fifth, eleventh and seventeenth aspects are obtained. That is, when the stair-like cross-sectional shape is formed in the twentieth aspect, deterioration of the quality of a hexagonal single crystal layer in the process of growing a new hexagonal single crystal layer can be reduced to a minimum.

A twenty-fifth aspect of the present invention is the method for producing a hexagonal single crystal according to any one of the twentieth to twenty-fourth aspects, further comprising:

setting the height of steps at 2 μm or more, but 1 mm or less, the spacing between the steps at 10 μm or more, but 10 mm or less, and the number of the steps at 5 or more, in forming the cross-sectional shape which is decreased in crystal thickness in a stair-step manner toward the second directions having the angle of 30°±15° from the direction opposite to the first direction.

According to the present aspect, the same actions and effects as those in the sixth, twelfth and nineteenth aspects are obtained. That is, when the patterned steps intersect the threading dislocations in the twentieth aspect, the probability of the threading dislocations being deflected toward the basal plane can be increased. Moreover, the height of the steps, the spacing between the steps, and the number of the steps can be rendered appropriate.

A twenty-sixth aspect of the present invention is the method for producing a hexagonal single crystal according to any one of the first to twenty-fifth aspects, further comprising:

performing the crystal growth by a chemical vapor deposition method, a sublimation method, or a solution growth method.

A twenty-seventh aspect of the present invention is the method for producing a hexagonal single crystal according to any one of the first to twenty-sixth aspects, wherein

the temperature of the crystal growth is 1400 to 2500° C.

A twenty-eighth aspect of the present invention is a method for producing a hexagonal single crystal wafer, comprising:

either using a hexagonal single crystal layer prepared by the method for producing a hexagonal single crystal according to any one of the first to twenty-seventh aspects, or slicing the hexagonal single crystal layer, to prepare the hexagonal single crystal wafer.

According to the present aspect, a hexagonal single crystal wafer having a low threading dislocation density can be obtained.

A twenty-ninth aspect of the present invention is a method for producing a hexagonal single crystal wafer, comprising:

either using a hexagonal single crystal layer prepared by the method for producing a hexagonal single crystal according to any one of the first to twenty-seventh aspects, or slicing the hexagonal single crystal layer, to prepare a hexagonal single crystal wafer; and

further either applying again the method for producing a hexagonal single crystal according to any one of the first to twenty-seventh aspects to the hexagonal single crystal wafer, to produce a hexagonal single crystal layer having a lower threading dislocation density, and using the resulting hexagonal single crystal layer;

or slicing the hexagonal single crystal layer,

thereby preparing the hexagonal single crystal wafer.

According to the present aspect, the same process is performed twice. Thus, a hexagonal single crystal wafer having an even lower threading dislocation density than in the twenty-eighth aspect can be obtained.

A thirtieth aspect of the present invention is a method for producing a hexagonal single crystal wafer, comprising:

either using a hexagonal single crystal layer prepared by the method for producing a hexagonal single crystal according to any one of the first to twenty-first aspects, or slicing the hexagonal single crystal layer, to prepare a hexagonal single crystal wafer; and

further either applying again the method for producing a hexagonal single crystal according to any one of the first to twenty-first aspects to the hexagonal single crystal wafer, with the reference line being shifted by 5° or more, but 15° or less, or by 60°±10°, to produce a hexagonal single crystal layer having a lower threading dislocation density, and using the resulting hexagonal single crystal layer;

or slicing the hexagonal single crystal layer,

thereby preparing the hexagonal single crystal wafer.

A thirty-first aspect of the present invention is a hexagonal single crystal wafer: which is prepared by the method for producing a hexagonal single crystal wafer according to any one of the twenty-eighth to thirtieth aspects; which has a hexagonal single crystal layer having a lower threading dislocation density than a hexagonal single crystal wafer prepared from the original hexagonal single crystal as the foundation for performing the crystal growth; and which is obtained by slicing the hexagonal single crystal layer.

According to the present aspect, a hexagonal single crystal wafer having a low threading dislocation density can be provided.

A thirty-second aspect of the present invention is a hexagonal single crystal wafer:

which is prepared by the method for producing a hexagonal single crystal wafer according to the twenty-eighth or twenty-ninth aspect; and

in which 50% or more of the total number of the threading dislocations contained in the hexagonal single crystal wafer are contained in

a region of a width ±5 mm from the single reference line along the first direction, in which the off angle is set, toward the second directions on both sides of the reference line and orthogonal to the first direction,

regions of a width ±5 mm from each of a plurality of reference lines along the first direction, and from an intermediate line between the two adjacent reference lines along the first direction, toward the second directions,

a region of a width ±5 mm from a single reference line orthogonal to the first direction toward the first direction,

regions of a width ±5 mm from each of a plurality of reference lines orthogonal to the first direction, and from an intermediate line between the two adjacent reference lines, toward the first direction, or

a region within 10 mm from one end of the wafer.

According to the present aspect, the threading dislocations are concentrated on the vicinity of the reference line or reference lines, or on the end of the wafer, whereby the threading dislocations in other regions can be reduced to obtain a high quality wafer.

A thirty-third aspect of the present invention is a hexagonal single crystal wafer:

which is prepared by the method for producing a hexagonal single crystal wafer according to the twenty-eighth or twenty-ninth aspect; and

in which 50% or more of the total number of the threading dislocations contained in the hexagonal single crystal wafer and having a c-axis direction component in Burgers vector are contained in

a region of a width ±5 mm from the single reference line along the first direction, in which the off angle is set, toward the second directions on both sides of the reference line and orthogonal to the first direction,

regions of a width ±5 mm from each of a plurality of reference lines along the first direction, and from an intermediate line between the two adjacent reference lines, toward the second directions,

a region of a width ±5 mm from a single reference line orthogonal to the first direction toward the first direction,

regions of a width ±5 mm from each of a plurality of reference lines orthogonal to the first direction, and from an intermediate line between the two adjacent reference lines, toward the first direction, or

a region within 10 mm from one end of the wafer.

According to the present aspect, the threading dislocations are concentrated on the vicinity of the reference line or reference lines, or on the end of the wafer, whereby the threading dislocations in other regions can be reduced to obtain a high quality wafer.

A thirty-fourth aspect of the present invention is a hexagonal single crystal wafer:

which is prepared by the method for producing a hexagonal single crystal wafer according to the thirtieth aspect; and

in which 50% or more of the total number of the threading dislocations contained in the hexagonal single crystal wafer are contained in

a region within a diameter of 1 cm² from a point where the single reference line set during the first crystal growth and the other single reference line set during the second crystal growth intersect, and

regions within a diameter of 1 cm² each from a plurality of points where the plurality of reference lines set during the first crystal growth and the intermediate line between the two adjacent reference lines, and the other plurality of reference lines set during the second crystal growth and the intermediate line between the two adjacent reference lines intersect.

According to the present aspect, the threading dislocations are concentrated on the vicinity of the reference lines, whereby the threading dislocations in other regions can be reduced to obtain a high quality wafer.

A thirty-fifth aspect of the present invention is a hexagonal single crystal wafer:

which is prepared by the method for producing a hexagonal single crystal wafer according to the thirtieth aspect; and

in which 50% or more of the total number of the threading dislocations contained in the hexagonal single crystal wafer and having a c-axis direction component in Burgers vector are contained in

a region within a diameter of 1 cm² from a point where the single reference line set during the first crystal growth and the other single center line set during the second crystal growth intersect, and

regions within a diameter of 1 cm² each from a plurality of points where the plurality of reference lines set during the first crystal growth and the intermediate line between the two adjacent reference lines, and the other plurality of reference lines set during the second crystal growth and the intermediate line between the two adjacent reference lines intersect.

According to the present aspect, the threading dislocations are concentrated on the vicinity of the reference lines, whereby the threading dislocations in other regions can be reduced to obtain a high quality wafer.

A thirty-sixth aspect of the present invention is a hexagonal single crystal element, which is obtained by the method for producing a hexagonal single crystal wafer according to any one of the twenty-eighth to thirtieth aspects.

According to the present aspect, a semiconductor element equipped with a hexagonal single crystal layer having a low threading dislocation density can be provided.

A thirty-seventh aspect of the present invention is the method for producing a hexagonal single crystal according to any one of the first to twenty-seventh aspects, wherein

the hexagonal single crystal is a silicon carbide single crystal.

A thirty-eighth aspect of the present invention is the method for producing a hexagonal single crystal wafer according to any one of the twenty-eighth to thirtieth aspects, wherein

the hexagonal single crystal wafer is a silicon carbide single crystal wafer.

A thirty-ninth aspect of the present invention is the hexagonal single crystal wafer according to any one of the thirty-first to thirty-fifth aspects, wherein

the hexagonal single crystal wafer is a silicon carbide single crystal wafer.

A fortieth aspect of the present invention is the hexagonal single crystal element according to the thirty-sixth aspect, wherein

the hexagonal single crystal element is a silicon carbide single crystal element.

### Effects of the Invention

According to the present invention, in the process of forming a new hexagonal single crystal layer on the original hexagonal single crystal, the threading dislocations contained in the original single crystal can be deflected toward the basal plane to discharge the threading dislocations out of the crystal, whereby a hexagonal single crystal layer having a lower threading dislocation density than that of the original hexagonal single crystal substrate can be obtained.

According to the present invention, moreover, a hexagonal single crystal wafer having a low threading dislocation density can be obtained.

Furthermore, according to the present invention, a semiconductor element provided with a hexagonal single crystal layer having a low threading dislocation density can be obtained.

### BRIEF DESCRIPTION OF THE DRAWINGS

FIGS. 1(a) and 1(b) are a plan view and a sectional view, respectively, of a silicon carbide single crystal wafer in a first embodiment of the present invention.

FIGS. 2(a) to 2(c) are views of stripes in the first embodiment of the present invention.

FIGS. 3(a) and 3(b) are a plan view and a sectional view, respectively, of the silicon carbide single crystal wafer in the first embodiment of the present invention.

FIGS. 4(a) and 4(b) are a plan view and a sectional view, respectively, of the silicon carbide single crystal wafer in the first embodiment of the present invention.

FIGS. 5(a) and 5(b) are a plan view and a sectional view, respectively, of another silicon carbide single crystal wafer in the first embodiment of the present invention.

FIG. 6 is a schematic view of a silicon carbide single crystal wafer obtained by slicing a silicon carbide single crystal layer shown in FIGS. 3(a), 3(b) along lines BB′, CC′.

FIGS. 7(a) and 7(b) are a plan view and a sectional view, respectively, of a silicon carbide single crystal formed with stepped patterns in a second embodiment of the present invention.

FIGS. 8(a) and 8(b) are a plan view and a sectional view, respectively, showing a new silicon carbide single crystal layer grown on the silicon carbide single crystal formed with the stepped patterns in FIGS. 7(a), 7(b).

FIG. 9 is a schematic view of a silicon carbide single crystal wafer obtained by slicing the silicon carbide single crystal layer, which is shown in FIGS. 8(a), 8(b) and has a lower threading dislocation density than in the original silicon carbide single crystal, along lines CC′, DD′.

FIGS. 10(a) and 10(b) are a plan view and a sectional view, respectively, showing a silicon carbide single crystal formed with stepped patterns according to a third embodiment of the present invention.

FIGS. 11(a) and 11(b) are a plan view and a sectional view, respectively, showing the silicon carbide single crystal formed with the stepped patterns according to the third embodiment of the present invention.

FIGS. 12(a) and 12(b) are a plan view and a sectional view, respectively, showing a silicon carbide single crystal formed with stepped patterns according to a fourth embodiment of the present invention.

FIGS. 13(a) and 13(b) are a plan view and a sectional view, respectively, showing the silicon carbide single crystal formed with the stepped patterns according to the fourth embodiment of the present invention.

FIGS. 14(a) and 14(b) are a plan view and a sectional view, respectively, showing the silicon carbide single crystal formed with the stepped patterns according to the fourth embodiment of the present invention.

FIGS. 15(a) and 15(b) are a plan view and a sectional view, respectively, showing the silicon carbide single crystal formed with the stepped patterns according to the fourth embodiment of the present invention.

FIGS. 16(a) and 16(b) correspond to FIGS. 3(a), 3(b), FIG. 16(a) being a photograph showing a defect image (planar image) obtained by making X-ray topography measurement of a new silicon carbide single crystal layer having a thickness of about 480 μm after formation of the silicon carbide single crystal layer; and FIG. 16(b) being a sectional schematic view of the defect image.

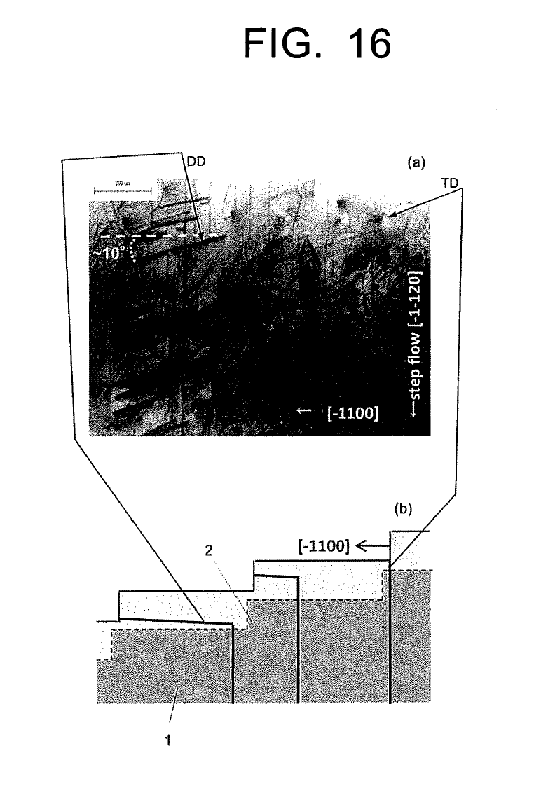

FIG. 17 is a photograph showing a defect image (sectional transmission image) obtained by making X-ray topography measurement of a section of the same silicon carbide single crystal layer as above.

FIGS. 18(a) and 18(b) are photographs showing defect images (planar images) obtained by making X-ray topography measurements of a new silicon carbide single crystal layer having a thickness of about 480 μm after formation of the silicon carbide single crystal layer, with the step height of stepped patterns formed on a silicon carbide single crystal being changed from 1 μm up to 10 μm.

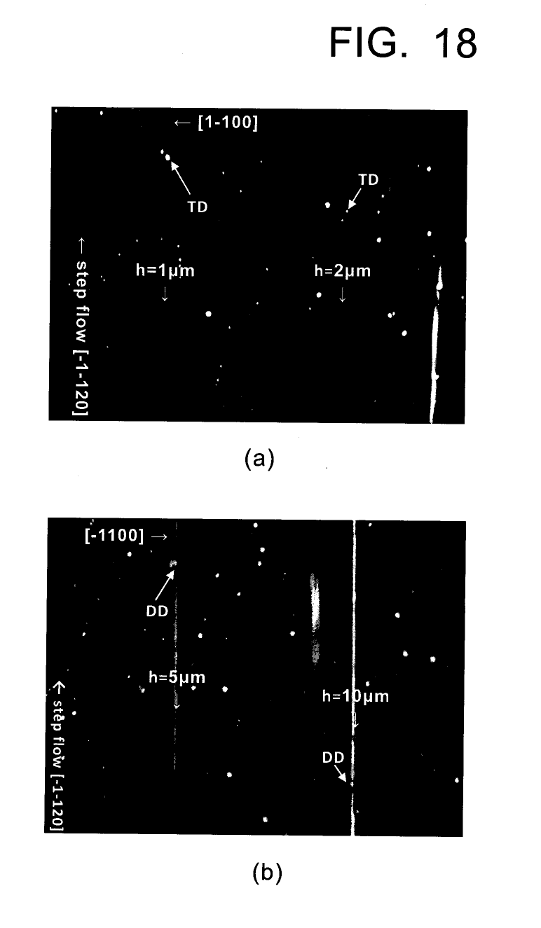

### MODE FOR CARRYING OUT THE INVENTION

### <Method for Reducing Threading Dislocations of Silicon Carbide Single Crystal Wafer>

The principles of a reduction in threading dislocations contained in a silicon carbide single crystal wafer obtained by the present invention will be briefly described first of all. As stated earlier (see “Background Art”), it has been reported that in silicon carbide vapor phase epitaxial growth on a crystal growth plane having an off angle of 0° to 10° from a basal plane {0001} ((0001) Si plane or (000-1) C plane; the same applies hereinafter), threading screw dislocations within a substrate propagate as such into an epitaxial film. If, in silicon carbide crystal growth, the off angle from the basal plane {0001} is large (for example, 50° or more), on the other hand, it is shown that the threading dislocations are deflected toward the basal plane, so that the threading screw dislocations within the substrate or seed crystal can be reduced. Also, in silicon carbide crystal growth, the threading dislocations are shown to be deflected toward the basal plane by macrosteps of a large step height.

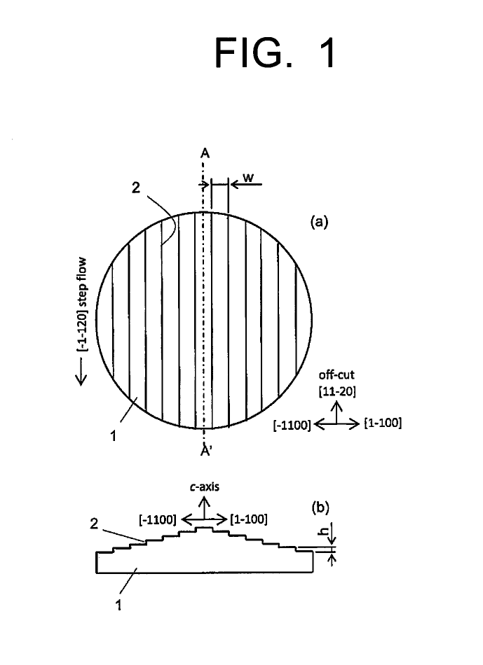

A silicon carbide single crystal wafer obtained by the present invention is produced by forming stepped patterns of any of first to fourth embodiments shown in FIGS. 1(a), 1(b) to 15(a), 15(b) on an original silicon carbide single crystal serving as a foundation, which comprises a silicon carbide single crystal substrate or an epitaxial film-provided silicon carbide single crystal substrate, and growing a new silicon carbide single crystal layer by a vapor phase growth method or a sublimation method or a solution growth method. The first to fourth embodiments of the present invention will be described in detail below by reference to the accompanying drawings.

### First Embodiment

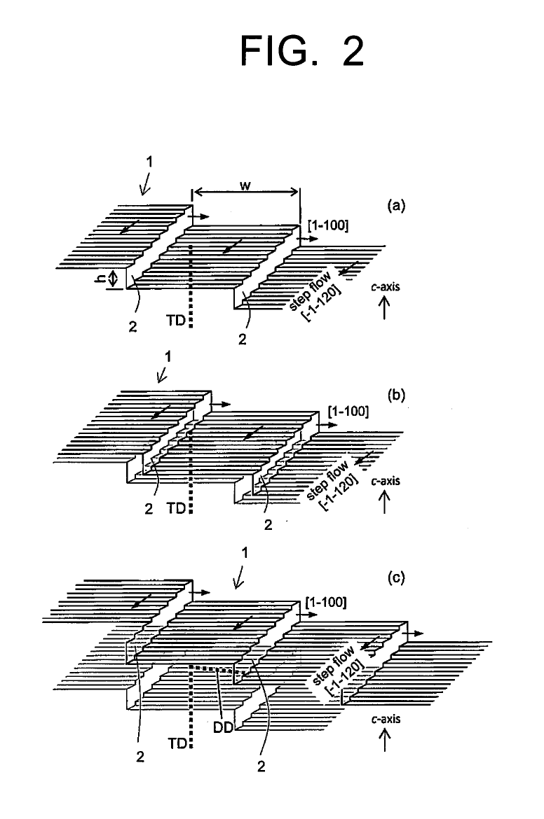

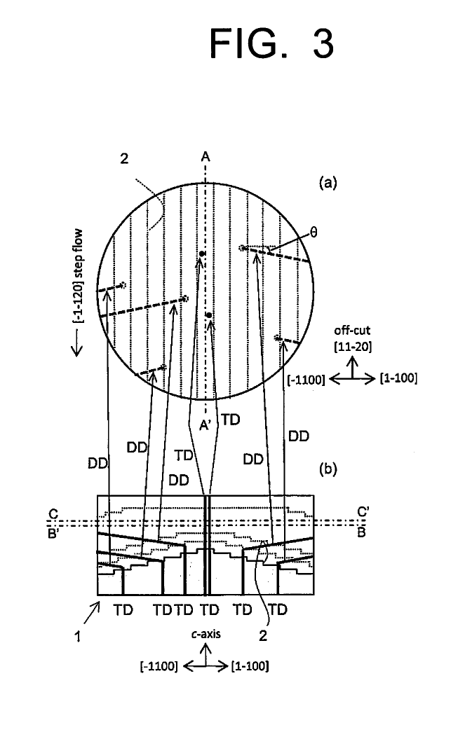

FIG. 1(a) is a plan view of a silicon carbide single crystal formed with stepped patterns in the first embodiment of the present invention. FIG. 1(b) is a sectional view of the silicon carbide single crystal formed with the stepped patterns in the first embodiment of the present invention. FIGS. 2(a) to 2(c) are stereographic views showing a new silicon carbide single crystal layer grown on the silicon carbide single crystal formed with the stepped patterns. FIG. 3(a) is a plan view showing the new silicon carbide single crystal layer grown on the silicon carbide single crystal formed with the stepped patterns. FIG. 3(b) is a sectional view showing the new silicon carbide single crystal layer grown on the silicon carbide single crystal formed with the stepped patterns.

As shown in FIGS. 1(a), 1(b), a cross-sectional shape, which is decreased in crystal thickness in a stair-step manner from a reference line AA′ (in the present example, the center line of a wafer formed from a silicon carbide single crystal 1 (the same applies hereinafter)) parallel (includes almost parallel; the same applies hereinafter) to a [11-20] direction toward a [−1100] direction and a [1-100] direction orthogonal to the [11-20] direction, is formed on the silicon carbide single crystal having an off angle in the [11-20] direction with respect to a basal plane {0001} serving as a main crystal growth plane.

As shown in FIG. 2(a), threading dislocations TDs (threading screw dislocations and threading edge dislocations) are contained in the silicon carbide single crystal 1 formed with the stepped patterns, and the leading end of the threading dislocations TDs appears on the surface of the silicon carbide single crystal 1. Since the off angle is set in the [11-20] direction from the basal plane {0001} serving as the main crystal growth plane, moreover, microscopic steps nearly parallel to the [1-100] direction are formed. Furthermore, since the stepped patterns are formed, patterned steps 2 parallel to the [11-20] direction and having a height h are formed generally with a spacing W.

When a new silicon carbide single crystal layer is grown on the silicon carbide single crystal 1 formed with the stepped patterns, the microscopic steps parallel to the [1-100] direction advance in a [−1-120] direction and, at the same time, the patterned steps 2 parallel to the [11-20] direction and having the height h advance in the [1-100] direction (a [−1100] direction, on the opposite side from the reference line AA′ shown in FIG. 1(a) (the same applies hereinafter)). That is, those steps advance in the directions indicated by arrows in the drawing.

As shown in FIG. 2(b), before the patterned steps 2 advancing in the [1-100] direction (on the opposite side from the reference line AA′, the [−1100] direction) pass the threading dislocations, most of the threading dislocations TDs propagate generally in a c-axis direction.

As shown in FIG. 2(c), when the patterned steps 2 advancing in the [1-100] direction (on the opposite side from the reference line AA′, the [−1100] direction) cross the threading dislocations TDs, most of the threading dislocations TDs are deflected toward the basal plane (hereinafter, the threading dislocations tilted greatly toward the basal plane, or the threading dislocations converted into basal plane defects will be referred to as deflected dislocations DDs) by the patterned steps 2, and then propagate in the single crystal while tilting greatly from the c-axis toward the basal plane. At this time, under the influences of both the microscopic steps advancing in the [−1-120] direction and the patterned steps 2 advancing in the [1-100] direction (on the opposite side from the reference line AA′, the [−1100] direction), the direction of propagation, in the basal plane, of the deflected dislocations DDs changes into a direction between the [−1-120] direction and the [1-100] direction (on the opposite side from the reference line AA′, a direction between the [−1-120] direction and the [−1100] direction).

In this manner, as shown in FIG. 3(a), the deflected dislocations DDs changed in the propagation direction from the threading dislocations TDs by intersection with the patterned steps 2 have an inclination angle [symbol] of several tens of degrees from the c-axis toward the basal plane with the progress of the patterned steps 3. Such defects DDs propagate toward the wafer end while having an angle θ of several tens of degrees or less in the [−1-120] direction relative to the [1-100] direction or the [−1100] direction. Finally, these defects DDs are discharged to the outside of the crystal at the wafer end. The deflected dislocations are discharge to the outside of the crystal more efficiently as the inclination angle of the deflected dislocations with respect to the c-axis increases, and this angle is preferably 40° or more, more preferably 45° or more.

At this time, as shown in FIG. 3(b), the threading dislocations TDs located at the highest step of the stepped patterns in the vicinity of the wafer center line are not intersected by the patterned steps 2 during crystal growth. Thus, they do not change into deflected dislocations DDs, but continue to propagate toward the crystal surface while remaining to be the threading dislocations TDs.

By so stacking silicon carbide single crystal layers in the c-axis direction of the stepwise silicon carbide single crystal 1 serving as the foundation, the threading dislocations TDs are gradually converted into deflected dislocations DDs and discharged out of the crystal. As a result, the threading dislocations TDs remain concentratedly at the uppermost part of the stepped patterns.

In order that the quality of the silicon carbide single crystal layer does not deteriorate in the process of growing a new silicon carbide single crystal layer, the main crystal growth plane preferably has an off angle of 10° or less (0.1° to 10°) with respect to the basal plane {0001}. That is, as the off angle increases, the crystal thickness necessary to discharge the deflected dislocation DD increases, while as the off angle decreases, the frequency of occurrence of a new crystal defect increases. Thus, it is more preferred for the main crystal growth plane to have an off angle of 0.5° to 5°.

In regard to the cross-sectional shape which is decreased in crystal thickness in a stair-step manner from the reference AA′ parallel to the first direction toward the second directions orthogonal to the first direction, it is required to increase the probability of conversion of the threading dislocations TDs into deflected dislocations DDs when the patterned steps 2 intersect the threading dislocations TDs. For this purpose, in forming the cross-sectional shape decreased in crystal thickness in a stair-step manner, the angle of the steps is preferably set at 45° or more, more preferably 55° or more, from the {0001} plane. If the angle of the steps is less than 54.7° corresponding to the angle which the basal plane forms with a (03-38) plane, the probability of conversion of the threading dislocations TDs into the deflected dislocations DDs when the patterned steps 2 intersect the threading dislocations TDs decreases, so that the proportion of the threading dislocations TDs propagating in the c-axis direction and remaining in the crystal increases. Further, if the angle of the steps is less than 45° from the basal plane, more of the threading dislocations TDs propagate in the c-axis direction and remain within the crystal.

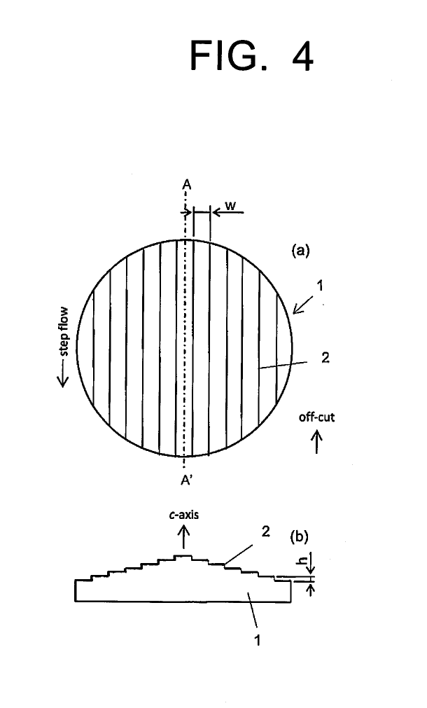

In forming the cross-sectional shape which is decreased in crystal thickness in a stair-step manner from the reference AA′ parallel to the first direction toward the second directions orthogonal to the first direction, it is required not to deteriorate the quality of the silicon carbide single crystal layer in the process of growing a new silicon carbide single crystal layer. For this purpose, it is preferred to set the first direction to be within ±10° from the <11-20> direction, and set the second directions to be within ±10° from the <1-100> direction and <−1100> direction orthogonal to the first direction. Depending on the state of crystal growth, however, it is permissible to set the first direction at any direction, as shown in FIGS. 4(a), 4(b). That is, the reference line AA′ shown in FIGS. 4(a), 4(b) need not necessarily be one along the <11-20> direction.

In forming the cross-sectional shape which is decreased in crystal thickness in a stair-step manner toward the second directions orthogonal to the first direction, moreover, it is required to render small the longest distance until the deflected dislocation DD is discharged to the wafer end. For this purpose, it is preferred to set the reference line AA′ along the first direction to be in a range of ±10 mm from the center of the silicon carbide single crystal 1 serving as the foundation. Depending on the state of crystal growth, however, it is acceptable to set the reference line AA′ parallel to the first direction to be displaced by any distance from the center of the silicon carbide single crystal 1 serving as the foundation. That is, the reference line AA′ need not necessarily pass the center of the wafer.

In regard to the cross-sectional shape which is decreased in crystal thickness in a stair-step manner from the wafer center line along the first direction toward the second directions orthogonal to the first direction, it is required to increase the probability of conversion of the threading dislocations TDs into deflected dislocations DDs when the patterned steps intersect the threading dislocations TDs. For this purpose, it is preferred to set the height of the steps at 2 μm or more, but 1 mm or less, and a spacing between the steps at 10 mm or less. If the height of the steps is less than 2 μm, the probability of conversion of the threading dislocations TDs into the deflected dislocations DDs when the patterned steps 2 intersect the threading dislocations TDs decreases, so that the proportion of the threading dislocations TDs propagating in the c-axis direction and remaining in the crystal increases. If the spacing between the steps exceeds 10 mm, the average distance until the patterned steps 2 intersect the threading dislocations TDs increases, and the shape of the patterned steps 2 cannot be retained. Thus, the probability of conversion of the threading dislocations TDs into the deflected dislocations DDs decreases, and so the proportion of the threading dislocations TDs propagating in the c-axis direction and remaining in the crystal increases.

In order to minimize the thickness of the original silicon carbide single crystal 1 as the foundation for performing crystal growth, it is preferred to set the height of the steps at 1 mm or less, and the spacing between the steps at 10 μm or more. Based on these conditions, the step height of 2 μm or more, but 1 mm or less, and the step spacing of 10 μm or more, but 10 mm or less are preferred ranges. In view of the facts that the general thickness of the original silicon carbide single crystal 1 is several millimeters or less and the height for practical use in the formation of the stepped patterns is 100 μm or less, the step height of 2 μm or more, but 100 μm or less, and the step spacing of 100 μm or more, but 1 mm or less are more preferred ranges. The number of the steps is 1 at the smallest counting from the reference line AA′, but when the diameter of the original silicon carbide single crystal 1 as the foundation for performing crystal growth is several centimeters or more and the step spacing is 10 mm or less, the number of the steps is preferably 5 or more.

A general method for forming the cross-sectional shape decreased in crystal thickness in a stair-step manner is lithography used in semiconductor processes. A mask is formed on the silicon carbide single crystal 1, and the mask is patterned. Then, the surface of the silicon carbide single crystal 1 being an aperture is subjected to etching (for example, dry etching with a reactive plasma using an etching gas such as CF₄ or SF₆). The mask may be such a mask or etching conditions as to have a selective ratio enabling the silicon carbide single crystal surface to be etched by 2 μm or more. As the mask, a resist film, for example, is capable of patterning in any shape, and can form any stripes.

The use of a material generally having a high selective ratio for silicon carbide, such as an SiO₂ film, an aluminum film or a nickel film, can bring the step height of the stepped patterns to several μm or more. Other approaches, such as machining, laser processing, and electrochemical etching, are considered applicable, and any methods can be applied, if they exhibit, in principle, the effects of structural conversion of the threading dislocations TDs and their discharge to the outside of the crystal, the effects described in the present embodiment.

The crystal growth of a new silicon carbide single crystal layer after formation of the stepped patterns may be single crystal growth of the same crystal type as that of the silicon carbide single crystal 1 formed with the stepped patterns, and includes the chemical vapor deposition (CVD) method, the sublimation method, or the solution growth method. In order to achieve single crystal growth of the same crystal type as the silicon carbide single crystal 1 formed with the stepped patterns, it is generally preferred to set the crystal growth temperature at 1400 to 2500° C.

According to the chemical vapor deposition method, a new silicon carbide single crystal layer can be obtained on the wafer of the silicon carbide single crystal 1 generally with the use, as the material, of a gas containing Si such as SiH₄ and a C-containing gas such as C₃H₈ or C₂H₄.

With the sublimation method, a silicon carbide powder as the material is placed in a crucible, and a silicon carbide seed crystal is installed on the upper surface of the inside of the crucible so as to face the silicon carbide powder. At this time, the crucible is heated to 2200° C. or higher to sublimate the silicon carbide powder. The sublimated silicon carbide powder is recrystallized on the opposing silicon carbide seed crystal, whereby a new silicon carbide single crystal is grown on the seed crystal.

With the solution growth method, a silicon lump as a material is charged into a crucible, and heated to the melting point of silicon or a higher temperature to form the silicon lump into a liquid. Also, carbon is mixed into the silicon liquid, for example, by forming the crucible from a carbon material, thereby preparing a solution comprising the silicon and carbon. In order to improve the meltability of carbon, an additive such as a metal may be incorporated into the solution. A silicon carbide single crystal is brought into contact with the resulting solution, whereby a new silicon carbide single crystal layer is crystallographically grown on the silicon carbide single crystal.

A cross-sectional shape is formed which is decreased in crystal thickness in a stair-step manner, for example, from the line AA′ as the center of the substrate extending along the first direction of the silicon carbide single crystal 1 serving as the foundation for crystal growth toward the second directions orthogonal to the first direction. A new silicon carbide single crystal layer is crystallographically grown thereon to a sufficient thickness. By this procedure, the patterned steps 2 of the stepped patterns intersect the threading dislocations TDs during crystal growth to convert the threading dislocations TDs contained in the original silicon carbide single crystal 1 into deflected dislocations DDs. In this manner, the deflected dislocations DDs are discharged from the crystal end to the outside of the crystal, whereby a silicon carbide single crystal layer decreased in the density of the threading dislocations TDs can be obtained.

By slicing the silicon carbide single crystal layer, which has been produced by the method for producing a silicon carbide single crystal according to the present embodiment and which has a lower threading dislocation density than the original silicon carbide single crystal 1, there can be prepared a silicon carbide single crystal wafer decreased in the threading dislocations TDs.

A silicon carbide semiconductor element can be produced using the silicon carbide single crystal wafer. The producible silicon carbide semiconductor element includes unipolar devices such as a schottky barrier diode (SBD), a junction barrier diode (JBS), a merged pin schottky diode (MPS), a junction field effect transistor (J-FET), and a metal oxide semiconductor field effect transistor (MOS-FET), and bipolar devices such as a pn diode, a bipolar junction transistor (BJT), a thyristor, a GTO thyristor, and an insulated gate bipolar transistor (IGBT).

The silicon carbide single crystal wafer obtained by slicing the silicon carbide single crystal layer having a lower threading dislocation density than in the original silicon carbide single crystal 1, which has been prepared by the method for producing a silicon carbide single crystal according to the present embodiment, can be one in which 50% or more of the total number of the threading dislocations TDs contained in the single crystal wafer are contained in a region of a width ±5 mm from any reference line AA′ along the first direction for setting the off angle (off-cut direction) toward the second directions on both sides of the reference line and orthogonal to the first direction.

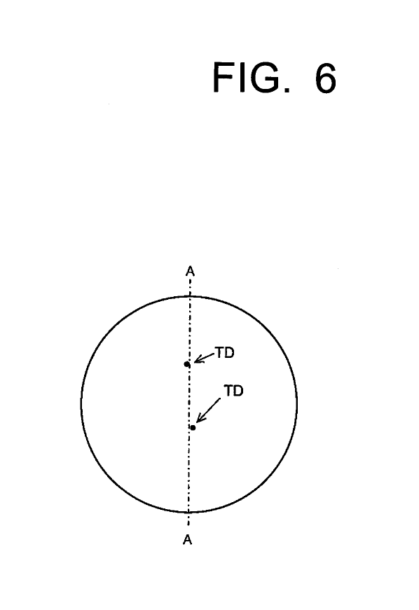

FIG. 6 is a schematic view of the silicon carbide single crystal wafer obtained by slicing along reference lines BB′, CC′ the silicon carbide single crystal layer having a lower threading dislocation density than in the original silicon carbide single crystal 1 shown in FIGS. 3(a), 3(b). As shown in FIG. 6, the threading dislocations TDs are present only in the vicinity of the reference line AA′ along the first direction in which the off angle is set as shown in FIGS. 3(a), 3(b).

The silicon carbide single crystal wafer obtained by slicing the silicon carbide single crystal layer having a lower threading dislocation density than in the original silicon carbide single crystal 1, which has been prepared by the method for producing a silicon carbide single crystal according to the present embodiment, is desirably one in which 50% or more of the total number of the threading dislocations TDs contained in the single crystal wafer and having a c-axis direction component in Burgers vector are contained in a region of a width ±5 mm from any reference line AA′ parallel to the first direction for setting the off angle toward the second directions on both sides of the reference line AA′ and orthogonal to the first direction.

The silicon carbide single crystal wafer obtained by slicing the silicon carbide single crystal layer having a lower threading dislocation density than in the original silicon carbide single crystal 1, which has been prepared by the method for producing a silicon carbide single crystal according to the present embodiment, is subjected again to the same method for producing a silicon carbide single crystal, whereby a silicon carbide single crystal layer having an even lower threading dislocation density than in the original silicon carbide single crystal 1 can be produced. At this time, the reference line AA′ during the second crystal growth with respect to the reference line AA′ during the first crystal growth is rotated at an angle to the <11-20> direction in the basal plane, whereby the threading dislocations TDs remaining near the reference line AA′ can be discharged except those near the point of intersection of the first reference line AA′ and the second reference line AA′. This rotation angle is preferably 5° or more. However, if the first reference line AA′ is nearly parallel to the [11-20] direction, it is preferred that the second reference line AA′ be nearly parallel to a [−2110] or [1-210] direction rotated by ±60° from the first reference line AA′ (“nearly parallel” means within ±10° from the [−2110] or [1-210] direction). If the first reference line AA′ is nearly parallel to the [1-100] direction, on the other hand, it is preferred that the second reference line AA′ be nearly parallel to a [10-10] or [0-110] direction rotated by ±60° from the first reference line AA′ (“nearly parallel” means within ±10° from the [10-10] or [0-110] direction).

A silicon carbide single crystal wafer obtained by slicing the silicon carbide single crystal layer having an even lower threading dislocation density than in the original silicon carbide single crystal 1, which has been prepared by applying again the same method for producing a silicon carbide single crystal, with the reference line AA′ being rotated by 5° or more, or 60°±10°, to the silicon carbide single crystal wafer obtained by slicing the silicon carbide single crystal layer having a lower threading dislocation density than in the original silicon carbide single crystal 1, which has been prepared by the method for producing a silicon carbide single crystal according to the present embodiment, is desirably one in which 50% or more of the total number of the threading dislocations TDs having a c-axis direction component in Burgers vector contained in the single crystal wafer are contained in a region within a diameter of 1 cm² from a point where the reference line AA′ set during the first crystal growth and the reference line AA′ set during the second crystal growth intersect.

### Second Embodiment

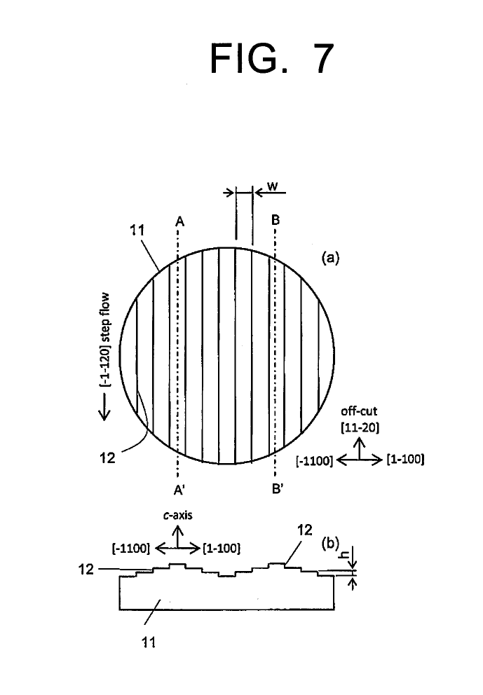

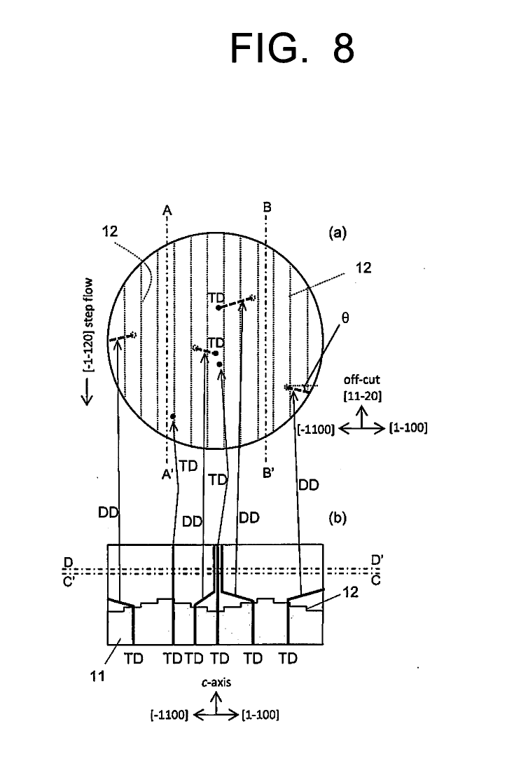

FIG. 7(a) is a plan view of a silicon carbide single crystal formed with stepped patterns in the second embodiment of the present invention. FIG. 7(b) is a sectional view of the silicon carbide single crystal formed with the stepped patterns in the second embodiment of the present invention. FIG. 8(a) is a plan view showing a new silicon carbide single crystal layer grown on the silicon carbide single crystal formed with the stepped patterns of FIGS. 7(a), 7(b). FIG. 8(b) is a sectional view showing the new silicon carbide single crystal layer grown on the silicon carbide single crystal formed with the stepped patterns of FIGS. 7(a), 7(b).

As shown in FIGS. 7(a), 7(b), a silicon carbide single crystal 1 in the present embodiment has an off angle in a [11-20] direction from a basal plane {0001} serving as a main crystal growth plane. On the silicon carbide single crystal 1, a cross-sectional shape is formed which is decreased in crystal thickness in a stair-step manner from a plurality of (two in the present embodiment) reference lines AA′, BB′ along the [11-20] direction toward a [−1100] direction and a [1-100] direction orthogonal to the [11-20] direction. There may be any number of the reference lines AA′, BB′.

In the present embodiment, as shown in FIGS. 8(a), 8(b), threading dislocations TDs are contained in the silicon carbide single crystal 11 formed with the stepped patterns and, in the silicon carbide single crystal 11, the leading ends of the threading dislocations TDs appear on the surface of the silicon carbide single crystal 11. Since the off angle is set in the [11-20] direction from the basal plane {0001} serving as the main crystal growth plane, moreover, microscopic steps nearly parallel to the [1-100] direction are formed. Further, since the stepped patterns are formed, patterned steps 12 parallel to the [11-20] direction and having a height h are formed generally with a spacing W.

In the present embodiment, when a new silicon carbide single crystal layer is grown on the silicon carbide single crystal 1 formed with the stepped patterns, the microscopic steps parallel to the [1-100] direction advance in a [−1-120] direction and, at the same time, the patterned steps 2 parallel to the [11-20] direction and having the height h advance in the [1-100] direction (on the opposite side from the reference lines AA′, BB′, the [−1100] direction; the same applies hereinafter).

Outwardly of the reference line AA′ in the single crystal (in the [−1100] direction from the reference line AA′) and outwardly of the reference line BB′ in the single crystal (in the [1-100] direction from the reference line BB′), most of the threading dislocations TDs are converted into deflected dislocations DDs by the patterned steps 12, are then greatly tilted from the c-axis direction toward the basal plane, and propagate within the single crystal. Finally, the deflected dislocations DDs are discharged to the outside of the crystal at the wafer end. In discharging the deflected dislocations out of the crystal, the larger the inclination angle of the deflected dislocation from the c-axis, the higher the efficiency of discharge is, and this angle is preferably 40° or more, more preferably 45° or more. At this time, as shown in FIGS. 8(a), 8(c), the threading dislocations TDs located at the highest step of the stepped patterns in the vicinity of the reference line AA′ and the reference line BB′ are not intersected by the patterned steps 2 during crystal growth. Thus, they are not converted into deflected dislocations DDs, but continue to propagate toward the crystal surface while remaining to be the threading dislocations TDs.

Inwardly of the reference line AA′ in the single crystal (in the [1-100] direction from the reference line AA′) and inwardly of the reference line BB′ in the single crystal (in the [−1100] direction from the reference line BB′), most of the threading dislocations TDs are converted into deflected dislocations DDs by the patterned steps 12, are then greatly tilted from the c-axis direction toward the basal plane, and propagate within the single crystal. Thus, they are concentrated on a region nearly intermediate between the reference line AA′ and the reference line BB′. Finally, they are converted again into threading dislocations TDs, and continue to propagate toward the surface of the crystal.

In order that the quality of the silicon carbide single crystal layer does not deteriorate in the process of growing a new silicon carbide single crystal layer, the main crystal growth plane preferably has an off angle of 10° or less (0.1° to 10°) with respect to the basal plane {0001}. As the off angle increases here, the crystal thickness necessary to discharge the deflected dislocations DDs increases, while as the off angle decreases, the frequency of occurrence of a new crystal defect increases. Thus, it is more preferred for the main crystal growth plane to have an off angle of 0.5° to 5°.

In regard to the cross-sectional shape which is decreased in crystal thickness in a stair-step manner from the reference lines AA′, BB′ parallel to the first direction toward the second directions orthogonal to the first direction, it is required to increase the probability of conversion of the threading dislocations TDs into the deflected dislocations DDs when the patterned steps 12 intersect the threading dislocations TDs. For this purpose, in forming the cross-sectional shape decreased stepwise in crystal thickness, the angle of the steps is preferably set at 45° or more from the {0001} plane. If the angle of the steps is less than 54.7° corresponding to the angle which the basal plane forms with a (03-38) plane, the probability of conversion of the threading dislocations TDs into the deflected dislocations DDs when the patterned steps 12 intersect the threading dislocations TDs decreases, so that the proportion of the threading dislocations TDs propagating in the c-axis direction and remaining in the crystal increases. Further, if the angle of the steps is less than 45° relative to the basal plane, more of the threading dislocations TDs propagate in the c-axis direction and remain within the crystal.

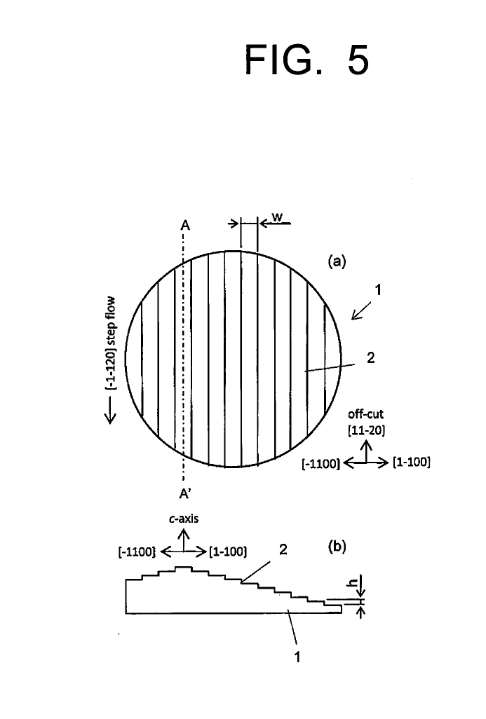

In forming the cross-sectional shape which is decreased in crystal thickness in a stair-step manner from the reference lines AA′, BB′ parallel to the first direction toward the second directions orthogonal to the first direction, it is required not to deteriorate the quality of the silicon carbide single crystal layer in the process of growing a new silicon carbide single crystal layer. For this purpose, it is preferred to set the first direction to be within ±10° from the <11-20> direction, and set the second directions to be within ±10° from the <1-100> direction and <−1100> direction orthogonal to the first direction. Depending on the state of crystal growth, however, it is permissible to set the first direction at any direction, as shown in FIGS. 5(a), 5(b).

In forming the cross-sectional shape which is decreased in crystal thickness in a stair-step manner from a plurality of reference lines alones the first direction toward the second directions, moreover, it is required to render small the longest distance until the deflected dislocation DD is discharged to the wafer end. For this purpose, it is preferred to set one of intermediate lines between the two adjacent parallel reference lines to be in a range of ±10 mm from the center of the silicon carbide single crystal 1 serving as the foundation. Depending on the state of crystal growth, however, it is acceptable to set one of the intermediate lines between the two adjacent parallel reference lines to be displaced by any distance from the center of the silicon carbide single crystal 1 serving as the foundation.

In regard to the cross-sectional shape which is decreased in crystal thickness in a stair-step manner from the substrate center line along the first direction toward the second directions orthogonal to the first direction, it is required to increase the probability of conversion of the threading dislocations TDs into deflected dislocations DDs when the patterned steps intersect the threading dislocations TDs. For this purpose, it is preferred to set the height of the steps at 2 μm or more, and a spacing between the steps at 10 mm or less. If the height of the steps is less than 2 μm, the probability of conversion of the threading dislocations TDs into the deflected dislocations DDs when the patterned steps 2 intersect the threading dislocations TDs decreases, so that the proportion of the threading dislocations TDs propagating in the c-axis direction and remaining in the crystal increases. If the spacing between the steps exceeds 10 mm, the average distance until the patterned steps 2 intersect the threading dislocations TDs increases, and the shape of the patterned steps 2 cannot be retained. Thus, the probability of conversion of the threading dislocations TDs into the deflected dislocations DDs decreases, so that the proportion of the threading dislocations TDs propagating in the c-axis direction and remaining in the crystal increases. In order to minimize the thickness of the original silicon carbide single crystal 1 as the foundation for performing crystal growth, moreover, it is preferred to set the height of the steps at 1 mm or less, and the spacing between the steps at 10 μm or more. Based on these conditions, the step height of 2 μm or more, but 1 mm or less, and the step spacing of 10 μm or more, but 10 mm or less are preferred ranges. In view of the facts that the general thickness of the original silicon carbide single crystal 1 is several millimeters or less and the height for practical use in the formation of the stepped patterns is 100 μm or less, the step height of 2 μm or more, but 100 μm or less, and the step spacing of 100 μm or more, but 1 mm or less are more preferred ranges. The number of the steps is 1 at the smallest counting from the reference lines AA′, BB′, but when the diameter of the original silicon carbide single crystal 1 as the foundation for performing crystal growth is several centimeters or more and the step spacing is 10 mm or less, the number of the steps is preferably 5 or more.

A general method for forming the cross-sectional shape decreased in crystal thickness in a stair-step manner is lithography used in semiconductor processes, as in the first embodiment. A mask is formed on the silicon carbide single crystal, and the mask is patterned. Then, the surface of the silicon carbide single crystal being an aperture is subjected to etching (for example, dry etching with a reactive plasma using an etching gas such as CF₄ or SF₆). The mask may be such a mask or etching conditions as to have a selective ratio enabling the silicon carbide single crystal surface to be etched by 2 μm or more. As the mask, a resist film, for example, is capable of patterning in any shape, and can form any stripes.

The use of a material generally having a high selective ratio for silicon carbide, such as an SiO₂ film, an aluminum film or a nickel film, can bring the step height of the stepped patterns to several μm or more. Other approaches, such as machining, laser processing, and electrochemical etching, are considered applicable, and any methods can be applied to the present invention, if they exhibit, in principle, the effects of deflection of the threading dislocations TDs and their discharge to the outside of the crystal, the effects described in the present invention.

The crystal growth of a new silicon carbide single crystal layer after formation of the stepped patterns may be single crystal growth of the same crystal type as that of the silicon carbide single crystal 11 formed with the stepped patterns, and includes the chemical vapor deposition (CVD) method, the sublimation method, or the solution growth method. In order to achieve single crystal growth of the same crystal type as the silicon carbide single crystal formed with the stepped patterns, it is generally preferred to set the crystal growth temperature at 1400 to 2500° C.

According to the chemical vapor deposition (CVD) method, a new silicon carbide single crystal layer can be obtained on the silicon carbide single crystal wafer generally with the use, as the material, of a gas containing Si such as SiH₄ and a C-containing gas such as C₃H₈ or C₂H₄.

With the sublimation method, a silicon carbide powder as the material is placed in a crucible, and a silicon carbide seed crystal is installed on the upper surface of the inside of the crucible so as to face the silicon carbide powder. At this time, the crucible is heated to 2200° C. or higher to sublimate the silicon carbide powder. The sublimated silicon carbide powder is recrystallized on the opposing silicon carbide single crystal 11, whereby a new silicon carbide single crystal is grown on the seed crystal.

With the solution growth method, a silicon lump as a material is charged into a crucible, and heated to the melting point of silicon or a higher temperature to form the silicon lump into a liquid. Also, carbon is mixed into the silicon liquid, for example, by forming the crucible from a carbon material, thereby preparing a solution comprising the silicon and carbon. In order to improve the meltability of carbon, an additive such as a metal may be incorporated into the solution. A silicon carbide single crystal 11 is brought into contact with the resulting solution, whereby a new silicon carbide single crystal layer is grown on the silicon carbide single crystal 11.

A cross-sectional shape is formed which is decreased in crystal thickness in a stair-step manner, for example, from the reference lines AA′, BB′ parallel to the first direction of the silicon carbide single crystal 11 serving as the foundation for crystal growth toward the second directions orthogonal to the first direction. A new silicon carbide single crystal layer is grown thereon to a sufficient thickness. By this procedure, the patterned steps 12 of the stepped patterns intersect the threading dislocations TDs during crystal growth to convert the threading dislocations TDs contained in the original silicon carbide single crystal 11 into deflected dislocations DDs. These deflected dislocations DDs are discharged from the crystal end to the outside of the crystal, whereby a silicon carbide single crystal layer decreased in the density of the threading dislocations TDs can be obtained.

By slicing the silicon carbide single crystal layer, which has been produced by the method for producing a silicon carbide single crystal according to the present embodiment and which has a lower density of threading dislocations TDs than the original silicon carbide single crystal 11, there can be prepared a silicon carbide single crystal wafer decreased in the threading dislocations TDs. A silicon carbide semiconductor element can be produced using the resulting silicon carbide single crystal wafer. The producible silicon carbide semiconductor element includes unipolar devices such as a schottky barrier diode (SBD), a junction barrier diode (JBS), a merged pin schottky diode (MPS), a junction field effect transistor (J-FET), and a metal oxide semiconductor field effect transistor (MOS-FET), and bipolar devices such as a pn diode, a bipolar junction transistor (BJT), a thyristor, a GTO thyristor, and an insulated gate bipolar transistor (IGBT).

The silicon carbide single crystal wafer obtained by slicing the silicon carbide single crystal layer having a lower density of threading dislocations TDs than that of the original silicon carbide single crystal 11, which has been prepared by the method for producing a silicon carbide single crystal according to the present embodiment, can be one in which 50% or more of the total number of the threading dislocations TDs contained in the single crystal wafer are contained in regions of a width ±5 mm from each of a plurality of (two in the present embodiment) any reference lines AA′, BB′ along the first direction, in which the off angle is set, toward the second directions on both sides of these reference lines and orthogonal to the first direction; and in a region of a width ±5 mm from an intermediate line between the adjacent reference lines AA′, BB′ toward the second directions on both sides of the intermediate line and orthogonal to the first direction.

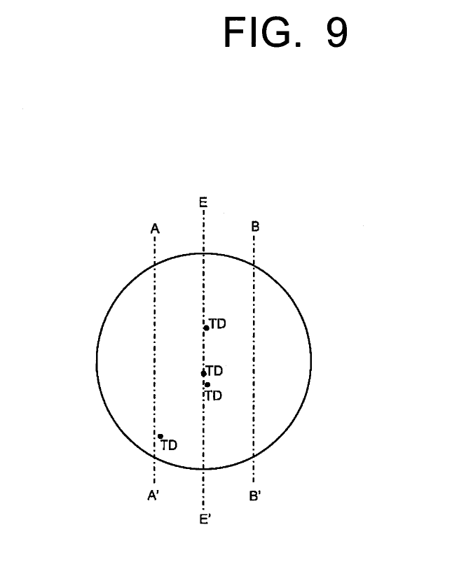

FIG. 9 is a schematic view of a silicon carbide single crystal wafer obtained by slicing along reference lines C-C′, D-D′ the silicon carbide single crystal layer having a lower threading dislocation density than the original silicon carbide single crystal shown in FIGS. 8(a), 8(b). As shown in FIG. 9, threading dislocations TDs are present only in the vicinity of the reference line AA′ and the vicinity of the reference line BB′ along the first direction, in which the off angle is set, as shown in FIGS. 8(a), 8(b), and in the vicinity of an intermediate line EE′ between the reference line AA′ and the reference line BB′. In this case, there may be any plural number of the reference lines AA′, BB′.

The silicon carbide single crystal wafer obtained by slicing the silicon carbide single crystal layer having a lower density of threading dislocations TDs than that of the original silicon carbide single crystal 11, which has been prepared by the method for producing a silicon carbide single crystal according to the present embodiment, is desirably configured to be one in which 50% or more of the total number of the threading dislocations TDs contained in the single crystal wafer and having a c-axis direction component in Burgers vector are contained in a region of a width ±5 mm from each of the plurality of any reference lines AA′, BB′ along the first direction, in which the off angle is set, toward the second directions on both sides of these reference lines and orthogonal to the first direction; and in a region of a width ±5 mm from an intermediate line between the adjacent reference lines AA′ and BB′ toward the second directions on both sides of these reference lines and orthogonal to the first direction.

Furthermore, the silicon carbide single crystal wafer obtained by slicing the silicon carbide single crystal layer having a lower density of threading dislocations TDs than the original silicon carbide single crystal 11, which has been prepared by the method for producing a silicon carbide single crystal according to the present embodiment, is subjected again to the same method for producing a silicon carbide single crystal as in the present embodiment, whereby a silicon carbide single crystal layer having an even lower density of threading dislocations TDs than the original silicon carbide single crystal 11 can be produced. At this time, the reference lines AA′, BB′ during the second crystal growth with respect to the reference lines AA′, BB′ during the first crystal growth are rotated at an angle to the <11-20> direction in the basal plane, whereby the threading dislocations TDs remaining near the reference lines AA′, BB′ can be discharged except those near the points of intersection of the first reference lines AA′, BB′ and the second reference lines AA′, BB′. The rotation angle at this time is preferably 5° or more. However, if the first reference lines AA′, BB′ are nearly parallel to the [11-20] direction, it is preferred that the second reference lines AA′, BB′ be nearly parallel to a [−2110] or [1-210] direction rotated by ±60° from the first reference lines AA′, BB′ (“nearly parallel” means within ±10° from the [−2110] or [1-210] direction). If the first reference lines AA′, BB′ are nearly parallel to the [1-100] direction, on the other hand, it is preferred that the second reference lines AA′, BB′ be nearly parallel to a [10-10] or [0-110] direction rotated by ±60° from the first reference lines AA′, BB′ (“nearly parallel” means within ±10° from the [10-10] or [0-110] direction).

A silicon carbide single crystal wafer obtained by slicing the silicon carbide single crystal layer having an even lower density of threading dislocations TDs than the original silicon carbide single crystal 11, which has been prepared by applying again the method for producing a silicon carbide single crystal according to the present embodiment, with the center line being rotated by 5° or more, or 60°±10°, to the silicon carbide single crystal wafer obtained by slicing the silicon carbide single crystal layer having a lower density of threading dislocations TDs than the original silicon carbide single crystal 11, which has been prepared by the same method for producing a silicon carbide single crystal according to the present embodiment, is desirably one in which 50% or more of the total number of the threading dislocations TDs contained in the single crystal wafer and having a c-axis direction component in Burgers vector are contained in a total of regions within a diameter of 1 cm² from each of a plurality of points where the plurality of (two in the present embodiment) reference lines AA′, BB′ set during the first crystal growth and the intermediate line between the two adjacent reference lines AA′, BB′, and the plurality of reference lines AA′, BB′ set during the second crystal growth and the intermediate line between the two adjacent reference lines AA′, BB′ intersect.

### Third Embodiment

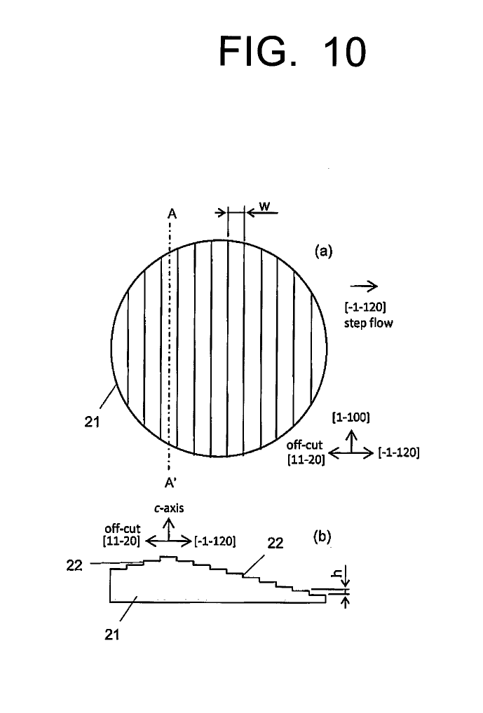

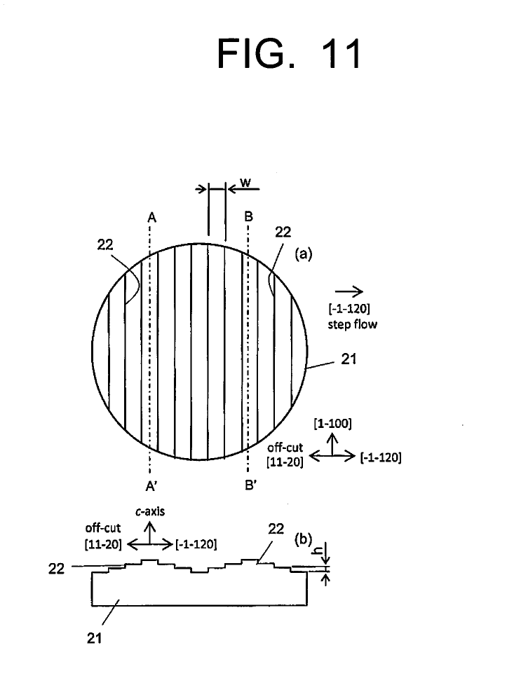

FIGS. 10(a), 10(b) and 11(a), 11(b) show plan views and sectional views of a silicon carbide single crystal formed with stepped patterns in the third embodiment of the present invention. In the present embodiment, as shown in FIGS. 10(a), 10(b) and 11(a), 11(b), a cross-sectional shape, which is decreased in crystal thickness in a stair-step manner from a single reference line AA′, or a plurality of reference lines AA′, BB′, orthogonal to a [11-20] direction toward the [11-20] direction and a [−1-120] direction opposite thereto, is formed on a silicon carbide single crystal 21 having an off angle in the [11-20] direction from a basal plane serving as a main crystal growth plane. In this case, any number of the reference lines AA′, BB′ may be present.

Threading dislocations TDs are contained in the silicon carbide single crystal 21 formed with the stepped patterns, and the leading ends of the threading dislocations TDs appears on the surface of the silicon carbide single crystal 21. Since the off angle is set in the [11-20] direction from the basal plane {0001} serving as the main crystal growth plane, moreover, microscopic steps nearly parallel to the [1-100] direction are formed. Further, since the stepped patterns are formed, patterned steps 22 parallel to the [1-100] direction and having a height h are formed generally with a spacing W.

When a new silicon carbide single crystal layer is grown on the silicon carbide single crystal 21 formed with the stepped patterns, the patterned steps 22 parallel to the [1-100] direction advance in the [−1-120] direction and, at the same time, the patterned steps parallel to the [1-100] direction and having the height h advance in the [−1-120] direction and the [11-20] direction opposite to it.

If the reference line is single as shown in FIG. 10, on the [−1-120] direction side and the [11-20] direction side of the reference line AA′, most of the threading dislocations TDs are converted into deflected dislocations DDs by the patterned steps 22, and then they propagate in the basal plane. Thus, they are finally discharged to the outside of the crystal at the wafer end. In discharging the deflected dislocations out of the crystal, the larger the inclination angle of the deflected dislocation from the c-axis, the higher the efficiency of discharge is, and this angle is preferably 40° or more, more preferably 45° or more. At this time, the threading dislocations TDs located at the highest step of the stepped patterns in the vicinity of the wafer center line are not intersected by the patterned steps 22 during crystal growth. Thus, they are not converted into deflected dislocations DDs, but continue to propagate toward the crystal surface while remaining to be the threading dislocations TDs.

If there are a plurality of reference lines as shown in FIGS. 11(a), 11(b), outwardly of the reference line AA′ in the silicon carbide single crystal 21 (in the [11-20] direction from the reference line AA′) and outwardly of the reference line BB′ in the silicon carbide single crystal 21 (in the [−1-120] direction from the reference line BB′), most of the threading dislocations TDs are converted into deflected dislocations DDs by the patterned steps 22, and then they propagate in the basal plane. Thus, they are finally discharged to the outside of the crystal at the wafer end. At this time, the threading dislocations TDs located at the highest step of the stepped patterns in the vicinity of the reference line AA′ and the reference line BB′ are not intersected by the patterned steps 22 during crystal growth. Thus, they are not converted into deflected dislocations DDs, but continue to propagate toward the crystal surface while remaining to be the threading dislocations TDs.

Inwardly of the reference line AA′ in the silicon carbide single crystal 21 (in the [−1-120] direction from the reference line AA′) and inwardly of the reference line BB′ in the single crystal (in the [11-20] direction from the reference line BB′), on the other hand, most of the threading dislocations TDs are converted into deflected dislocations DDs by the patterned steps 22, and then the deflected dislocations propagate in the basal plane. Thus, they are concentrated on a region nearly intermediate between the reference line AA′ and the reference line BB′. Finally, they are converted again into threading dislocations TDs, and continue to propagate toward the surface of the crystal.

In both of a case where the single reference line exists and a case where the plurality of reference lines exist, in order that the quality of the new silicon carbide single crystal layer does not deteriorate in the process of growing a new silicon carbide single crystal layer, the main crystal growth plane preferably has an off angle of 10° or less (0.1° to 10°) with respect to the basal plane. As the off angle increases here, the crystal thickness necessary to discharge the deflected dislocations DDs increases, while as the off angle decreases, the frequency of occurrence of a new threading dislocation TD increases. Thus, it is more preferred for the main crystal growth plane to have an off angle of 0.5° to 5°.

In regard to the cross-sectional shape which is decreased in crystal thickness in a stair-step manner, it is required to increase the probability of conversion of the threading dislocations TDs into deflected dislocations DDs when the patterned steps 22 intersect the threading dislocations. For this purpose, in forming the cross-sectional shape decreased in crystal thickness in a stair-step manner, the angle of the steps is preferably set at 45° or more, more preferably 55° or more, from the {0001} plane. If the angle of the steps is less than 54.7° corresponding to the angle which the basal plane forms with a (03-38) plane, the probability of conversion of the threading dislocations TDs into the deflected dislocations DDs when the patterned steps 22 intersect the threading dislocations TDs decreases, so that the proportion of the threading dislocations TDs propagating in the c-axis direction and remaining in the crystal increases. Further, if the angle of the steps is less than 45° relative to the basal plane, more of the threading dislocations TDs propagate in the c-axis direction and remain within the crystal.

In forming the cross-sectional shape which is decreased in crystal thickness in a stair-step manner, it is required not to deteriorate the quality of a new silicon carbide single crystal layer in the process of growing the new silicon carbide single crystal layer. For this purpose, it is preferred to set a direction, in which the crystal thickness is decreased in a stair-step manner, to be within ±10° from the <11-20> direction, or within ±10° from the <1-100> direction. Depending on the state of crystal growth, however, it is permissible to set the direction, in which the crystal thickness is decreased in a stair-step manner, to be any direction.

In forming the cross-sectional shape which is decreased in crystal thickness in a stair-step manner, it is required to render small the longest distance until the deflected dislocation DD is discharged to the wafer end. For this purpose, the following conditions are preferred: 1) In the case of the single reference line, the reference line AA′ orthogonal to the direction in which the crystal thickness is decreased in a stair-step manner is set in a range of ±10 mm from the center of the silicon carbide single crystal 21 serving as the foundation. 2) In the case of the plurality of reference lines, the reference lines AA's orthogonal to the direction in which the crystal thickness is decreased in a stair-step manner are set in a range of ±10 mm from the center of the silicon carbide single crystal 21 serving as the foundation. Depending on the state of crystal growth, however, it is acceptable to set the reference line AA′ to be displaced by any distance from the center of the silicon carbide single crystal 21 serving as the foundation, or to be located at the end of the silicon carbide single crystal 21.

In regard to the cross-sectional shape, which is decreased in crystal thickness in a stair-step manner, in the cases of the single reference line or the plurality of reference lines, it is required to increase the probability of conversion of the threading dislocations TDs into deflected dislocations DDs when the patterned steps 22 intersect the threading dislocations TDs. For this purpose, it is preferred to set the height of the steps at 2 μm or more, and the spacing between the steps at 10 mm or less. If the height of the steps is less than 2 μm, the probability of conversion of the threading dislocations TDs into the deflected dislocations DDs when the patterned steps 22 intersect the threading dislocations TDs decreases, so that the proportion of the threading dislocations TDs propagating in the c-axis direction and remaining in the new silicon carbide single crystal layer increases. If the spacing between the steps exceeds 10 mm, the average distance until the patterned steps 22 intersect the threading dislocations TDs increases, and the shape of the patterned steps cannot be retained. Thus, the probability of conversion of the threading dislocations TDs into the deflected dislocations DDs decreases, so that the proportion of the threading dislocations TDs propagating in the c-axis direction and remaining in the new silicon carbide single crystal layer increases. In order to minimize the thickness of the original silicon carbide single crystal 21 as the foundation for performing crystal growth, moreover, it is preferred to set the height of the steps at 1 mm or less, and the spacing between the steps at 10 μm or more. Based on these conditions, the step height of 2 μm or more, but 1 mm or less, and the step spacing of 10 μm or more, but 10 mm or less are preferred ranges. In view of the facts that the general thickness of the original silicon carbide single crystal 21 is several millimeters or less and the height for practical use in the formation of the stepped patterns is 100 μm or less, the step height of 2 μm or more, but 100 μm or less, and the step spacing of 100 μm or more, but 1 mm or less are more preferred ranges. The number of the steps is 1 at the smallest counting from the reference lines AA′, BB′, but when the diameter of the original silicon carbide single crystal 21 as the foundation for performing crystal growth is several centimeters or more and the step spacing is 10 mm or less, the number of the steps is preferably 5 or more.

A general method for forming the cross-sectional shape decreased in crystal thickness in a stair-step manner is lithography used in semiconductor processes, as in the first and second embodiments. That is, a mask is formed on the silicon carbide single crystal 21, and the mask is patterned. Then, the surface of the silicon carbide single crystal being an aperture is subjected to etching (for example, dry etching with a reactive plasma using an etching gas such as CF₄ or SF₆). The mask may be such a mask or etching conditions as to have a selective ratio enabling the silicon carbide single crystal surface to be etched by 1 μm or more. As the mask, a resist film, for example, is capable of patterning in any shape, and can form any stripes.

The use of a material generally having a high selective ratio for silicon carbide, such as an SiO₂ film, an aluminum film or a nickel film, can bring the step height of the stepped patterns to several μm or more. Other approaches, such as machining, laser processing, and electrochemical etching, are considered applicable, but any methods can be applied to the present invention, if they exhibit, in principle, the effects of structural conversion of threading dislocations TDs and their discharge to the outside of the crystal, the effects described in the present invention.

The crystal growth of a new silicon carbide single crystal layer after formation of the stepped patterns may be single crystal growth of the same crystal type as that of the silicon carbide single crystal 21 formed with the stepped patterns, and includes the chemical vapor deposition (CVD) method, the sublimation method, or the solution growth method. In order to achieve single crystal growth of the same crystal type as the silicon carbide single crystal 21 formed with the stepped patterns, it is generally preferred to set the crystal growth temperature at 1400 to 2500° C.

According to the chemical vapor deposition (CVD) method, a new silicon carbide single crystal layer can be obtained on the silicon carbide single crystal wafer generally with the use, as the material, of a gas containing Si such as SiH₄ and a C-containing gas such as C₃H₈ or C₂H₄.

With the sublimation method, it is common practice to charge a silicon carbide powder as the material into a crucible, and install a silicon carbide seed crystal on the upper surface of the inside of the crucible so as to face the silicon carbide powder. At this time, the crucible is heated to 2200° C. or higher to sublimate the silicon carbide powder. The sublimated silicon carbide powder is recrystallized on the opposing silicon carbide seed crystal, whereby a new silicon carbide single crystal is grown on the seed crystal.

With the solution growth method, a silicon lump as a material is charged into a crucible, and heated to the melting point of silicon or a higher temperature to form the silicon lump into a liquid. Also, carbon is mixed into the silicon liquid, for example, by forming the crucible from a carbon material, thereby preparing a solution comprising the silicon and carbon. In order to improve the meltability of carbon, an additive such as a metal may be incorporated into the solution. The silicon carbide single crystal is brought into contact with the resulting solution, whereby a new silicon carbide single crystal layer is grown on the silicon carbide single crystal.

A cross-sectional shape is formed which is decreased in crystal thickness in a stair-step manner from the reference lines AA′, BB′ of the silicon carbide single crystal 21 serving as the foundation for crystal growth toward the directions orthogonal to the reference lines. A new silicon carbide single crystal layer is crystallographically grown thereon to a sufficient thickness. By this procedure, the patterned steps 22 of the stepped patterns intersect the threading dislocations TDs during crystal growth to convert the threading dislocations TDs contained in the original silicon carbide single crystal 21 into deflected dislocations DDs. These deflected dislocations DDs are discharged from the crystal end to the outside of the crystal, whereby a silicon carbide single crystal layer decreased in the density of the threading dislocations TDs can be obtained.

By slicing the silicon carbide single crystal layer, which has been produced by the method for producing a silicon carbide single crystal according to the present embodiment and which has a lower density of threading dislocations TDs than the original silicon carbide single crystal 21, there can be prepared a silicon carbide single crystal wafer decreased in the threading dislocations TDs. Using the resulting silicon carbide single crystal wafer, a silicon carbide semiconductor element can be produced. The producible silicon carbide semiconductor element includes unipolar devices such as a schottky barrier diode (SBD), a junction barrier diode (JBS), a merged pin schottky diode (MPS), a junction field effect transistor (J-FET), and a metal oxide semiconductor field effect transistor (MOS-FET), and bipolar devices such as a pn diode, a bipolar junction transistor (BJT), a thyristor, a GTO thyristor, and an insulated gate bipolar transistor (IGBT).

The silicon carbide single crystal wafer obtained by slicing the silicon carbide single crystal layer having a lower density of threading dislocations TDs than that of the original silicon carbide single crystal 21, which has been prepared by the method for producing a silicon carbide single crystal according to the present embodiment, is preferably one in which 50% or more of the total number of the threading dislocations TDs contained in the single crystal wafer are contained in a region of a width ±5 mm from a single reference line AA′ orthogonal to the first direction, in which the off angle is set, toward the first direction, or regions of a width ±5 mm from each of a plurality of any reference lines AA′, BB′ orthogonal to the first direction, in which the off angle is set, toward the first direction; and in a region of a width ±5 mm from an intermediate line between the adjacent reference lines AA′, BB′ toward the first direction.

The silicon carbide single crystal wafer obtained by slicing the silicon carbide single crystal layer having a lower density of threading dislocations TDs than that of the original silicon carbide single crystal 21, which has been prepared by the method for producing a silicon carbide single crystal according to the present embodiment, is preferably one in which 50% or more of the total number of the threading dislocations contained in the single crystal wafer and having a c-axis direction component in Burgers vector are contained in a region of a width ±5 mm from a single reference line AA′ orthogonal to the first direction, in which the off angle is set, toward the first direction, or regions of a width ±5 mm from each of a plurality of any reference lines AA′, BB′ orthogonal to the first direction, in which the off angle is set, toward the first direction; and in a region of a width ±5 mm from an intermediate line between the adjacent center lines toward the first direction.

At this time, the threading dislocations TDs located at the highest step of the stepped patterns in the vicinity of the wafer end are not intersected by the patterned steps 32 during crystal growth. Thus, they are not converted into deflected dislocations DDs, but continue to propagate toward the crystal surface while remaining to be the threading dislocations TDs.

### Fourth Embodiment

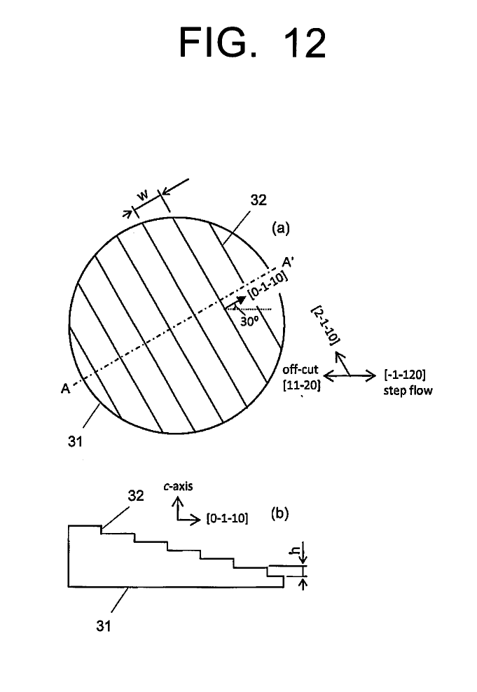

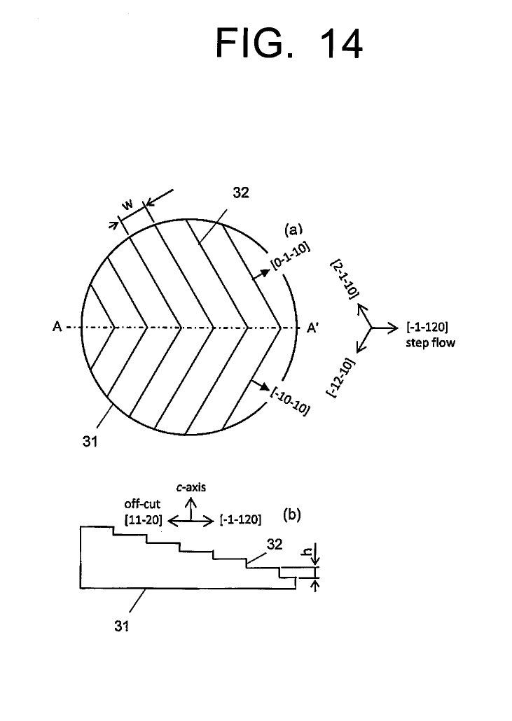

FIGS. 12(a), 12(b) to 15(a), 15(b) show plan views and sectional views of a silicon carbide single crystal formed with stepped patterns in the fourth embodiment of the present invention. In the present embodiment, as shown in FIG. 12(a), 12(b) or 13(a), 13(b), on a silicon carbide single crystal 31 having an off angle in a [11-20] direction from a basal plane serving as a main crystal growth plane, there is formed a cross-sectional shape which is decreased in crystal thickness in a stair-step manner from one end of the single crystal toward a [0-1-10] direction or a [−10-10] direction having an angle of 30° from a [−1-120] direction opposite to the [11-20] direction. Alternatively, as shown in FIG. 14(a), 14(b) or 15(a), 15(b), on the silicon carbide single crystal 31 having the off angle in the [11-20] direction from the basal plane serving as the main crystal growth plane, there may be formed a cross-sectional shape which is decreased in crystal thickness in a stair-step manner from one end of the single crystal toward both of the [0-1-10] direction and the [−10-10] direction having an angle of 30° from the [−1-120] direction opposite to the [11-20] direction, with a single reference line or a plurality of reference lines (AA′, AA's in FIGS. 14(a), (b), 15(a), 15(b)) parallel to the first direction, in which the off angle is set, being as the boundary.

Threading dislocations TDs are contained in the silicon carbide single crystal 31 formed with the stepped patterns, and the leading ends of the threading dislocations TDs appear on the surface of the silicon carbide single crystal 31. Since the off angle is set in the [11-20] direction from the basal plane {0001} serving as the main crystal growth plane, moreover, microscopic steps nearly parallel to the [1-100] direction orthogonal to the [11-20] direction are formed. Further, since the stepped patterns are formed, patterned steps 32 parallel to a [2-1-10] direction or a [−12-10] direction and having a height h are formed generally with a spacing W.

When a new silicon carbide single crystal layer is grown on the silicon carbide single crystal 31 formed with the stepped patterns, the patterned steps 32 parallel to the [2-1-10] direction or the [−12-10] direction and having the height h advance in the [0-1-10] direction or the [−10-10] direction, respectively.

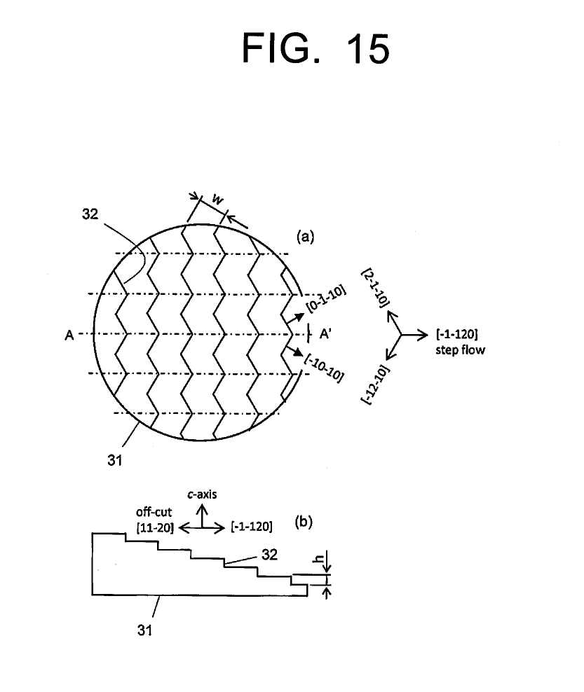

Most of the threading dislocations TDs are converted into deflected dislocations DDs by the patterned steps 32, and then the deflected dislocations DDs propagate in the single crystal toward directions between the advancing directions of the patterned steps and the [−1-120] direction, while greatly tilting from the c-axis direction toward the basal plane. Thus, the DDs are finally discharged to the outside of the crystal at the wafer end. In discharging the deflected dislocations out of the crystal, the larger the inclination angle of the deflected dislocation from the c-axis, the higher the efficiency of discharge is, and this angle is preferably 40° or more, more preferably 45° or more. If, here, the patterned steps parallel to the [2-1-10] direction and the patterned steps parallel to the [−12-10] direction are continuously formed as shown in FIGS. 15(a), 15(b), the threading dislocations TDs are converted into deflected dislocations DDs by the patterned steps 32, and then the deflected dislocations DDs propagate in the single crystal toward the [−1-120] direction, which is an intermediation direction between the [2-1-10] direction and the [−12-10] direction being the advancing direction of the patterned steps 32, while greatly tilting from the c-axis direction toward the basal plane. Thus, the DDs are finally discharged to the outside of the crystal at the wafer end. At this time, the threading dislocations TDs located at the highest step of the stepped patterns in the vicinity of the wafer end are not intersected by the patterned steps 32 during crystal growth. Thus, they are not converted into deflected dislocations DDs, but continue to propagate toward the crystal surface while remaining to be the threading dislocations TDs.

In FIGS. 12(a), 12(b), 13(a), 13(b), 14(a), 14(b) and 15(a), 15(b), the cross-sectional shape, which is decreased in crystal thickness in a stair-step manner from the one end of the single crystal toward the [0-1-10] direction, or the [−10-10] direction, having an angle of 30° from the [11-20] direction, is formed on the silicon carbide single crystal 31 having the off angle in the [11-20] direction from the basal plane serving as the main crystal growth plane. However, there may be formed the cross-sectional shape which is decreased in crystal thickness in a stair-step manner from any place in the single crystal toward the [0-1-10] direction or the [−10-10] direction having an angle of 30° from the [11-20] direction and, at the same time, toward the [10-10] direction or [01-10] direction, both directions opposite to those directions.

In order that the quality of the new silicon carbide single crystal layer does not deteriorate in the process of growing the new silicon carbide single crystal layer, the main crystal growth plane preferably has an off angle of 10° or less (0.1° to 10°) with respect to the basal plane. As the off angle increases here, the crystal thickness necessary to discharge the deflected dislocations DDs increases, while as the off angle decreases, the frequency of occurrence of a new threading dislocation TD increases. Thus, it is more preferred for the main crystal growth plane to have an off angle of 0.5° to 5°.

In order that the quality of the new silicon carbide single crystal layer does not deteriorate in the process of growing the new silicon carbide single crystal layer, moreover, it is preferred to set the direction, in which the off angle is set, to be within ±10° from the <11-20> direction, or within ±10° from the <1-100> direction. Depending on the state of crystal growth, however, it is permissible to set the direction, in which the off angle is set, to be any direction.

In regard to the cross-sectional shape which is decreased in crystal thickness in a stair-step manner, it is required to increase the probability of conversion of the threading dislocations TDs into deflected dislocations DDs when the patterned steps 32 intersect the threading dislocations. For this purpose, in forming the cross-sectional shape decreased in crystal thickness in a stair-step manner, the angle of the steps is preferably set at 45° or more, more preferably 55° or more, from the {0001} plane. If the angle of the steps is less than 54.7° corresponding to the angle which the basal plane forms with a (03-38) plane, the probability of conversion of the threading dislocations TDs into the deflected dislocations DDs when the patterned steps 32 intersect the threading dislocations TDs decreases, so that the proportion of the threading dislocations TDs propagating in the c-axis direction and remaining in the crystal increases. Further, if the angle of the steps is less than 45° relative to the basal plane, more of the threading dislocations TDs propagate in the c-axis direction and remain within the crystal.

In regard to the cross-sectional shape, which is decreased in crystal thickness in a stair-step manner, it is required to increase the probability of conversion of the threading dislocations TDs into deflected dislocations DDs when the patterned steps 32 intersect the threading dislocations TDs. For this purpose, it is preferred to set the height of the steps at 2 μm or more, and the spacing between the steps at 10 mm or less. If the height of the steps is less than 2 μm, the probability of conversion of the threading dislocations TDs into the deflected dislocations DDs when the patterned steps 32 intersect the threading dislocations TDs decreases, so that the proportion of the threading dislocations TDs propagating in the c-axis direction and remaining in the new silicon carbide single crystal layer increases. If the spacing between the steps exceeds 10 mm, the average distance until the patterned steps 32 intersect the threading dislocations TDs increases, and the shape of the patterned steps cannot be retained. Thus, the probability of conversion of the threading dislocations TDs into the deflected dislocations DDs decreases, so that the proportion of the threading dislocations TDs propagating in the c-axis direction and remaining in the new silicon carbide single crystal layer increases. In order to minimize the thickness of the original silicon carbide single crystal 31 as the foundation for performing crystal growth, moreover, it is preferred to set the height of the steps at 1 mm or less, and the spacing between the steps at 10 μm or more. Based on these conditions, the step height of 2 μm or more, but 1 mm or less, and the step spacing of 10 μm or more, but 10 mm or less are preferred ranges. In view of the facts that the general thickness of the original silicon carbide single crystal 31 is several millimeters or less and the height for practical use in the formation of the stepped patterns is 100 μm or less, the step height of 2 μm or more, but 100 μm or less, and the step spacing of 100 μm or more, but 1 mm or less are more preferred ranges. The number of the steps is 1 at the smallest, but when the diameter of the original silicon carbide single crystal 31 as the foundation for performing crystal growth is several centimeters or more and the step spacing is 10 mm or less, the number of the steps is preferably 5 or more.

A general method for forming the cross-sectional shape decreased in crystal thickness in a stair-step manner is lithography used in semiconductor processes, as in the first and second embodiments. That is, a mask is formed on the silicon carbide single crystal 31, and the mask is patterned. Then, the surface of the silicon carbide single crystal being an aperture is subjected to etching (for example, dry etching with a reactive plasma using an etching gas such as CF₄ or SF₆). The mask may be such a mask or etching conditions as to have a selective ratio enabling the silicon carbide single crystal surface to be etched by 1 μm or more. As the mask, a resist film, for example, is capable of patterning in any shape, and can form any stripes.

The use of a material generally having a high selective ratio for silicon carbide, such as an SiO₂ film, an aluminum film or a nickel film, can bring the step height of the stepped patterns to several μm or more. Other approaches, such as machining, laser processing, and electrochemical etching, are considered applicable, but any methods can be applied to the present invention, if they exhibit, in principle, the effects of structural conversion of the threading dislocations TDs and their discharge to the outside of the crystal, the effects described in the present invention.

The crystal growth of a new silicon carbide single crystal layer after formation of the stepped patterns may be single crystal growth of the same crystal type as that of the silicon carbide single crystal 31 formed with the stepped patterns, and includes the chemical vapor deposition (CVD) method, the sublimation method, or the solution growth method. In order to achieve single crystal growth of the same crystal type as the silicon carbide single crystal 31 formed with the stepped patterns, it is generally preferred to set the crystal growth temperature at 1400 to 2500° C.

According to the chemical vapor deposition (CVD) method, a new silicon carbide single crystal layer can be obtained on the silicon carbide single crystal wafer generally with the use, as the material, of a gas containing Si such as SiH₄ and a C-containing gas such as C₃H₈ or C₂H₄.

With the sublimation method, it is common practice to charge a silicon carbide powder into a crucible, and install a silicon carbide seed crystal on the upper surface of the inside of the crucible so as to face the silicon carbide powder. At this time, the crucible is heated to 2200° C. or higher to sublimate the silicon carbide powder. The sublimated silicon carbide powder is recrystallized on the opposing silicon carbide seed crystal, whereby a new silicon carbide single crystal is grown on the seed crystal.

With the solution growth method, a silicon lump as a material is charged into a crucible, and heated to the melting point of silicon or a higher temperature to form the silicon lump into a liquid. Also, carbon is mixed into the silicon liquid, for example, by forming the crucible from a carbon material, thereby preparing a solution comprising the silicon and carbon. In order to improve the meltability of carbon, an additive such as a metal may be incorporated into the solution. A silicon carbide single crystal is brought into contact with the resulting solution, whereby a new silicon carbide single crystal layer is crystallographically grown on the silicon carbide single crystal.

A cross-sectional shape is formed which is decreased in crystal thickness in a stair-step manner from one end of the silicon carbide single crystal 31 serving as the foundation for crystal growth toward a direction having an angle of 30° with respect to the direction opposite to the off direction. A new silicon carbide single crystal layer is crystallographically grown thereon to a sufficient thickness. By this procedure, the patterned steps 32 of the stepped patterns intersect the threading dislocations TDs during crystal growth to convert the threading dislocations TDs contained in the original silicon carbide single crystal 31 into deflected dislocations DDs. These deflected dislocations DDs are discharged from the crystal end to the outside of the crystal, whereby a silicon carbide single crystal layer decreased in the density of the threading dislocations TDs can be obtained.

By slicing the silicon carbide single crystal layer, which has been produced by the method for producing a silicon carbide single crystal according to the present embodiment and which has a lower density of threading dislocations TDs than the original silicon carbide single crystal 31, there can be prepared a silicon carbide single crystal wafer decreased in the threading dislocations TDs. Using the resulting silicon carbide single crystal wafer, a silicon carbide semiconductor element can be produced. The producible silicon carbide semiconductor element includes unipolar devices such as a schottky barrier diode (SBD), a junction barrier diode (JBS), a merged pin schottky diode (MPS), a junction field effect transistor (J-FET), and a metal oxide semiconductor field effect transistor (MOS-FET), and bipolar devices such as a pn diode, a bipolar junction transistor (BJT), a thyristor, a GTO thyristor, and an insulated gate bipolar transistor (IGBT).

The silicon carbide single crystal wafer obtained by slicing the silicon carbide single crystal layer having a lower density of threading dislocations TDs than that of the original silicon carbide single crystal 31, which has been prepared by the method for producing a silicon carbide single crystal according to the present embodiment, is preferably one in which 50% or more of the total number of the threading dislocations TDs contained in the single crystal wafer are contained in a region 10 mm or less, more preferably 5 mm or less, from one end of the single crystal; or a region at the highest step of the stepped patterns set at any place.

A silicon carbide single crystal wafer obtained by slicing the silicon carbide single crystal layer having a lower density of threading dislocations TDs than that of the original silicon carbide single crystal 31, which has been prepared by the method for producing a silicon carbide single crystal according to the present embodiment, is preferably one in which 50% or more of the total number of the threading dislocations contained in the single crystal wafer and having a c-axis direction component in Burgers vector are contained in a region 10 mm or less, more preferably 5 mm or less, from one end of the single crystal; or a region at the highest step of the stepped patterns set at any place.

Next, concrete working examples of the method for producing a silicon carbide single crystal according to the present invention will be described.

### Example 1

Example 1 concerns the method for production in the first embodiment (see FIGS. 1(a), 1(b), 2(a), 2(b), 2(c) and 3(a), 3(b)) utilizing the method of decreasing the density of threading dislocations contained in the silicon carbide single crystal 1. According to this production method, the threading dislocations TD in the silicon carbide single crystal were converted into deflected dislocations DD, and the deflected dislocations DD were discharged outside the crystal. As a result, a silicon carbide single crystal wafer having a low density of threading dislocations TD can be obtained. Using it, a silicon carbide semiconductor element free from influences on the element characteristics by the threading dislocations TD can be obtained. Consequently, applied equipment incorporating the silicon carbide semiconductor element, such as an inverter, can be improved in reliability.

Example 1 will be described concretely in the order of steps below.

### 1) Preparations for Silicon Carbide Single Crystal

Preparations are made for a silicon carbide single crystal substrate, or a silicon carbide single crystal substrate having an epitaxial film of the same crystal type as the substrate grown on the substrate. As a method of preparing an ingot for cutting out the silicon carbide single crystal substrate, and a method for growing the epitaxial film, various methods have already been developed, put to practical use, and commercially available. Using any of these methods, the silicon carbide single crystal 1 may be made ready for use.

As the crystal type of the epitaxial film or substrate in the silicon carbide single crystal 1 for production, a hexagonal crystal is desirable. The desirable lamination cycle is 4-fold (4H-SiC) or 6-fold (6H-SiC). The desirable crystal plane is the (000-1)C plane or the (0001)Si plane. The off angle is desirably 0° to 10° from the basal plane. The off-cut direction is desirably within ±10° from the <11-20> direction, but is not limited thereto, and may be the <1-100> direction or any direction. The silicon carbide single crystal to be produced is not intended for use in semiconductor applications, but is put to other uses.

### 2) Formation of Stair-Like Cross-Sectional Shape on Silicon Carbide Single Crystal

As shown in FIGS. 1(a), 1(b), a stair-like cross-sectional shape keeping an inclined surface at an inclination angle α of 55° or more from the basal plane is formed on the silicon carbide single crystal 1 by lithography used in semiconductor processes. That is, a mask is formed on the silicon carbide single crystal 1, and the mask is patterned. Then, the surface of the silicon carbide single crystal 1 being an aperture is subjected to etching. Alternatively, the stair-like cross-sectional shape may be formed by machining, laser processing, electrochemical etching, or the like.

The stair-like cross-sectional shape is formed such that the crystal thickness is decreased stepwise, with a reference line AA′ nearly parallel to the <11-20> direction being as the boundary, toward the single crystal substrate ends on both sides in the <1-100> direction and <−1100> direction orthogonal to the reference line AA′. As shown in FIGS. 1(a), 1(b), it is desirable to set the reference line AA′ nearly parallel to the <11-20> direction so as to pass nearly the center of the silicon carbide single crystal substrate. As shown in FIGS. 5(a), 5(b), however, it is also possible to set the reference line AA′ to be offset from the center of the single crystal substrate. The number of the steps is 1 at the smallest counting from the reference line AA′, but in many cases, 5 to 500 level differences or steps are formed on each side of the reference line AA′ on the silicon carbide single crystal wafer with a diameter of several inches, for example, 2 to 6 inches.

The method for forming the stair-like cross-section includes, for example, a method which comprises forming a mask material on the single crystal and performing taper turning and etching, for each step of stepped patterns; a method comprising forming beforehand a plurality of stepped patterns in a mask material by patterning and performing etching; or a method of forming a stair-like cross-sectional shape by machining, laser processing, electrochemical etching, or the like. In particular, a preferably applicable method for formation of a plurality of stepped patterns is a method which comprises coating a resist film, which is capable of control over any shape of a mask, to a thickness of 2 μm or more, and performing patterning three-dimensionally by a laser plotting device, in a mask patterning process; or using an SiO₂ film or the like with a thickness of the order of 100 nm to several μm as a mask, and performing patterning such as wet etching to form a taper angle.

An example of the etching method is dry etching with a reactive plasma using an etching gas containing F, such as CF₄ or SF₆. In order to stabilize the etching rate and the etching selective ratio in the step of dry etching, there are cited a method of sticking a mask-patterned silicon carbide single crystal to an etching support stand, and a method of cooling a substrate electrode.

The step of forming the stair-like cross section may cause damage, such as crystal defect or contamination, to the stepped inclined face and the surface. Thus, surface flattening by dry etching using an argon gas is performed during the etching step; alternatively, after the etching step, the surface is oxidized in an oxygen atmosphere at a temperature of the order of 1200° C., and the resulting oxide film is removed by etching; or single crystal growth pretreatment such as high temperature hydrogen etching or high temperature hydrogen chloride etching at a temperature of the order of 1500° C. is performed in the process of crystallizing a new silicon carbide single crystal layer. By such treatment, damage to the stepped inclined face and the surface, such as a crystal defect or contamination, can be eliminated.

### 3) Formation of New Silicon Carbide Single Crystal Layer on Silicon Carbide Single Crystal

For crystal growth of a new silicon carbide single crystal layer after formation of the stair-like cross section, the chemical vapor deposition method, the sublimation method, or the solution growth method is used to carry out single crystal growth of the same crystal type as that of the silicon carbide single crystal wafer. At this time, as shown in FIGS. 2(a) to 2(c) and 3(a), 3(b), the crystal growth of the new silicon carbide single crystal layer after formation of the stair-like cross section enables threading dislocations within the silicon carbide single crystal wafer to be greatly tilted from the c-axis direction toward the basal plane, converted thereby into deflected dislocations DDs, and discharged to the outside of the crystal.

### Example 2

Example 2 concerns the method for production in the first embodiment (see FIGS. 1(a), 1(b), 2(a), 2(b), 2(c) and 3(a), 3(b)) utilizing the method of decreasing the density of threading dislocations contained in the silicon carbide single crystal wafer mentioned above. In the present Example, the silicon carbide single crystal 1 was obtained by slicing a hexagonal four-fold cycle SiC (4H-SiC) single crystal ingot obtained by the sublimation method. The crystal plane was the (000-1)C plane, the off angle was 4° from the basal plane, and the off-cut direction was the <11-20> direction.

To the (000-1) C plane on which a new silicon carbide single crystal layer was to be grown, chemical mechanical polishing (CMP) was applied to eliminate surface damage due to slicing or subsequent mechanical polishing.

On the (000-1) C plane of the silicon carbide single crystal, a 6 μm thick SiO₂ film was formed by the chemical vapor deposition (CVD) method. The deposition temperature of SiO₂ by CVD was 450° C. After deposition of the SiO₂ film, a resist film was coated on the SiO₂ film to a thickness of about 1 μm, and a rectangular pattern was formed in the resist film by lithography used in semiconductor processes. The long side in the formation of the rectangular shape by patterning was set to be nearly parallel to the [11-20] direction which was the off-cut direction. Then, the SiO₂ film in a region without the resist film was etched away by treatment with hydrofluoric acid to form a rectangular SiO₂ film on the silicon carbide single crystal.

Then, the silicon carbide single crystal was subjected to ion coupling plasma (ICP) etching using the rectangular SiO₂ film as a mask and SF₆ as an etching gas to form a stepped shape having an inclined cross section nearly parallel to the [11-20] direction on the (000-1) C plane of the silicon carbide single crystal. At this time, the inclined cross section was formed at an inclination angle of about 80° from the (000-1) C plane. By repeating this procedure involving deposition of SiO₂, coating with the resist film, patterning of the resist film, SiO₂ etching, and silicon carbide etching, there was formed a cross-sectional shape decreased in crystal thickness in a 25-stairstep manner from a center line, which passed nearly the center of the silicon carbide single crystal and was parallel to the [11-20] direction, toward a [−1100] direction and a [1-100] direction orthogonal to the [11-20] direction.

The detailed parameters of the silicon carbide single crystal substrate formed with the stair-like cross section were as follows:

(1) Type and size of silicon carbide single crystal: 4H-SiC, diameter 2 inches, thickness 3 mm
(2) Main crystal growth plane of silicon carbide single crystal substrate: (000-1) C plane
(3) Off-cut of silicon carbide single crystal substrate: 4° off in [11-20] direction
(4) Center line of stair-like cross-sectional shape: Passing within ±1 mm from the center of the silicon carbide single crystal of 2 inches in diameter, and parallel to the [11-20] direction (within ±2° from the [11-20] direction)
(5) Height and width of one step in stepped patterns: About 10 μm high, about 500 μm wide
(6) Number of steps in stepped patterns: 25 steps each toward the [−1100] direction and the [1-100] direction from the center line

The above-mentioned stair-like cross section was formed on the (000-1) C plane of the silicon carbide single crystal 1, whereafter a new 4H-SiC silicon carbide single crystal layer was grown by the chemical vapor deposition method (CVD method). The growth of the new 4H-SiC silicon carbide single crystal layer by the chemical vapor deposition method was performed at a growth temperature of 1600° C. and an ambient pressure of 40 Torr using monosilane (SiH₄) and propane (C₃H₈) as materials and hydrogen (H₂) as a carrier gas. The crystal growth was carried out for about 50 hours to form a new silicon carbide single crystal layer with a thickness of about 480 μm.

FIGS. 12(a), 12(b) correspond to FIGS. 3(a), 3(b).

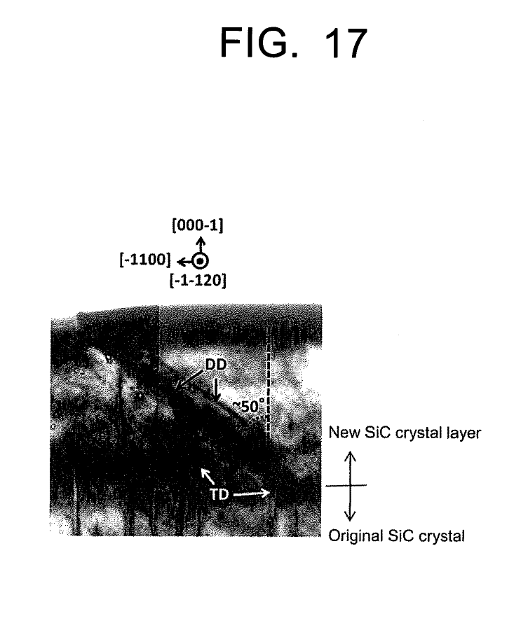

Incidentally, FIG. 12(a) shows a defect image (planar image) obtained by making X-ray topography measurement of the new silicon carbide single crystal layer having a thickness of about 480 μm after formation of the new silicon carbide single crystal layer. FIG. 12(b) is a sectional schematic view of the defect image. X-ray topography was performed in synchrotron radiation facilities under the condition g=11-20 with the use of X rays monochromatized to the energy of 17.48 keV. In FIG. 12(a), black rectilinear contrasts arranged in a direction tilted by an angle of the order of 10° from the [−1100] direction to the [−1-120] direction correspond to deflected dislocations (DD) which were converted, upon deflection during crystal growth, from threading dislocations in the original silicon carbide single crystal. As noted here, it can be confirmed by the present method that the threading dislocations were deflected in a direction at an angle of the order of 10° from the second direction [−1100] orthogonal to the first direction [11-20] direction toward the [−1-120] direction opposite to the first direction, and the resulting deflected dislocations DD were propagated in the single crystal, and eventually discharged to the outside of the crystal. This angle varies according to the off angle from the basal plane, the stepped patterns, and the crystal growth conditions, but is generally within 45°. FIG. 17 shows a defect image (sectional transmission image) obtained by making X-ray topography measurement of a cross section of the same silicon carbide single crystal layer. X-ray topography was performed in synchrotron radiation facilities under the condition g=0004 with the use of X rays monochromatized to the energy of 17.48 keV. Based on the cross-sectional defect image by the X-ray topography measurement, it can be confirmed that the threading dislocations TD in the original silicon carbide single crystal were deflected during crystal growth, and converted into deflected dislocations tilted by about 50° from the c-axis direction toward the basal plane. This tilt angle from the c-axis direction toward the basal plane varies according to the stepped patterns and the crystal growth conditions, but is generally within 40° or more.

### Example 3

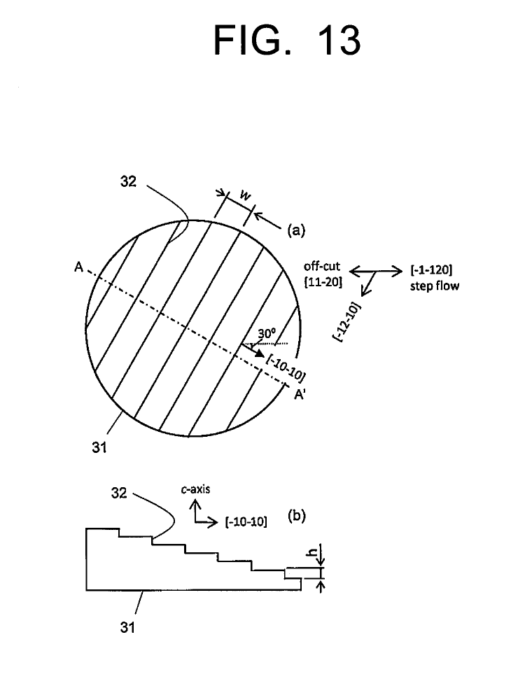

FIGS. 13(a), 13(b) show defect images (planar images) obtained by making X-ray topography measurements of a new silicon carbide single crystal layer having a thickness of about 480 μm after formation of the new silicon carbide single crystal layer, with the step height of the stepped patterns formed in a silicon carbide single crystal being changed from 1 μm to 10 μm. X-ray topography was performed in synchrotron radiation facilities under the condition 8=11-28 with the use of X rays monochromatized to the energy of 17.48 keV. The method of forming the stepped patterns and the method of crystal growth are the same as in Example 2.

FIG. 13(a) shows a photograph of the site where the step height of the stepped patterns was 1 μm, and the site where the step height of the stepped patterns was 2 μm. In this X-ray topography image, at the site where the step height was 1 μm, threading dislocations TDs were observed even in the place passed by the patterned steps during crystal growth. This finding confirms that the threading dislocations TDs contained in the original silicon carbide single crystal were not converted, but propagated onto the surface of the new crystal. When the step height was 1 μm, nearly 100% of the threading dislocations TDs contained in the original silicon carbide single crystal were found not to be converted.

When the step height of the stepped patterns was set at 2 μm, on the other hand, some of (more or less 20% of) the threading dislocations TDs contained in the original silicon carbide single crystal were confirmed to be converted into deflected dislocations DD upon passage by the patterned steps during new crystal growth.

Further, FIG. 13(b) shows a photograph of the site where the step height of the stepped patterns was 5 μm, and the site where the step height of the stepped patterns was 10 μm. In this X-ray topography image, at the site where the step height was 5 μm or 10 μm, deflected dislocations DDs generated upon great tilting of the threading dislocations TDs were observed in the place passed by the patterned steps during crystal growth. This finding confirms that the threading dislocations TDs contained in the original silicon carbide single crystal were converted into the deflected dislocations DDs, and the direction of propagation of the defects changed. Of the threading dislocations TDs contained in the original silicon carbide single crystal, it was found that nearly 80% were converted into the deflected dislocations DDs when the step height was 5 μm, and that 90% or more were converted into the deflected dislocations DDs when the step height was 10 μm.

As discussed above, in order to convert threading dislocations TDs contained in the original silicon carbide single crystal into deflected dislocations DDs during new crystal growth, the step height of the stepped patterns of 2 μm or more can be judged preferred.

The foregoing Embodiments and working Examples have been described in connection with the silicon carbide single crystal, but can be generally applied to any hexagonal single crystal, and the silicon carbide single crystal is not limitative. They can be applied preferably to aluminum nitride (AlN) and gallium nitride (GaN), in particular.

### INDUSTRIAL APPLICABILITY

The present invention can be utilized preferably in industrial fields where electronic devices using silicon carbide single crystals are applied.

### EXPLANATIONS OF LETTERS OR NUMERALS

1, 11, 21 Silicon carbide single crystal
2, 12, 22 Patterned step
AA′ Reference line
TD Threading dislocation
DD Deflected dislocation
h Height
w Spacing
Angle

1. A method for producing a hexagonal single crystal, comprising a process of growing a hexagonal single crystal,
the process comprising:
setting an off angle, in a first direction with respect to a basal plane serving as a main crystal growth plane, in the hexagonal single crystal for use as a foundation in performing crystal growth; and
forming a cross-sectional shape which is decreased in crystal thickness in a stair-step manner from a single reference line along the first direction toward second directions on both sides of the reference line and orthogonal to the first direction,
thereby converting dislocations threading in a c-axis direction, which are contained in the hexagonal single crystal, into defects inclined by 40° or more from the c-axis direction toward the basal plane during crystal growth, and controlling a direction of propagation of the defects to a direction between a direction opposite to the first direction and the second directions, to discharge the defects out of the crystal.

2. The method for producing a hexagonal single crystal according to claim 1, wherein
the main crystal growth plane has the off angle of 10° or less from the basal plane, and deflects and propagates the threading dislocations in a direction within 45° from the second directions on both sides toward the direction opposite to the first direction, thereby discharging the dislocations out of the crystal.

3. The method for producing a hexagonal single crystal according to claim 1, further comprising:
setting an angle of steps at 45° or more from the basal plane in forming the cross-sectional shape which is decreased in crystal thickness in a stair-step manner from a center line along the first direction toward the second directions.

4. The method for producing a hexagonal single crystal according to claim 1, wherein
the first direction is within ±10° from a <11-20> direction, and the second directions are within ±10° from a <1-100> direction and <−1100> direction orthogonal to the first direction.

5. The method for producing a hexagonal single crystal according to claim 1, further comprising:
setting the center line along the first direction to be in a range of ±10 mm from a center of the hexagonal single crystal serving as the foundation in forming the cross-sectional shape which is decreased in crystal thickness in a stair-step manner toward the second directions.

6. The method for producing a hexagonal single crystal according to claim 1, further comprising:
setting a height of steps at 2 μm or more, but 1 mm or less, a spacing between the steps at 10 μm or more, but 10 mm or less, and the number of the steps at 5 or more, in forming the cross-sectional shape which is decreased in crystal thickness in a stair-step manner from a center line along the first direction toward the second directions orthogonal to the first direction.

7. A method for producing a hexagonal single crystal, comprising a process of growing a hexagonal single crystal,
the process comprising:
setting an off angle, in a first direction with respect to a basal plane serving as a main crystal growth plane, in the hexagonal single crystal for use as a foundation in performing crystal growth; and
forming a cross-sectional shape which is decreased in crystal thickness in a stair-step manner from a plurality of reference lines along the first direction toward second directions on both sides of the reference lines and orthogonal to the first direction,
thereby converting dislocations threading in a c-axis direction, which are contained in the hexagonal single crystal, into defects inclined by 40° or more from the c-axis direction toward the basal plane during crystal growth, and controlling a direction of propagation of the defects to a direction between a direction opposite to the first direction and the second directions, to discharge the defects out of the crystal.

8. The method for producing a hexagonal single crystal according to claim 7, wherein
the main crystal growth plane has the off angle of 10° or less from the basal plane, and deflects and propagates the threading dislocations in a direction within 45° from the second directions on both sides toward the direction opposite to the first direction, thereby discharging the dislocations out of the crystal or near a line intermediate between the two adjacent reference lines along the first direction.

9. The method for producing a hexagonal single crystal according to claim 7, further comprising:
setting an angle of steps at 45° or more from the basal plane in forming the cross-sectional shape which is decreased in crystal thickness in a stair-step manner from a center line along the first direction toward the second directions orthogonal to the first direction.

10. The method for producing a hexagonal single crystal according to claim 7, wherein
the first direction is within ±10° from a <11-20> direction, and the second directions are within ±10° from a <1-100> direction and <−1100> direction orthogonal to the first direction.

11. The method for producing a hexagonal single crystal according to claim 7, further comprising:
setting one of the intermediate lines between the two adjacent parallel reference lines to be in a range of ±10 mm from a center of the single crystal in forming the cross-sectional shape which is decreased in crystal thickness in a stair-step manner from the plurality of reference lines along the first direction toward the second directions.

12. The method for producing a hexagonal single crystal according to claim 7, further comprising:
setting a height of steps at 2 μm or more, but 1 mm or less, a spacing between the steps at 10 μm or more, but 10 mm or less, and the number of the steps at 5 or more, in forming the cross-sectional shape which is decreased in crystal thickness in a stair-step manner from the plurality of reference lines along the first direction toward the second directions.

13. A method for producing a hexagonal single crystal, comprising a process of growing a hexagonal single crystal,
the process comprising:
setting an off angle, in a first direction with respect to a basal plane serving as a main crystal growth plane, in the hexagonal single crystal for use as a foundation in performing crystal growth; and
forming a cross-sectional shape which is decreased in crystal thickness in a stair-step manner from a single reference line or a plurality of reference lines orthogonal to the first direction toward the first direction and a direction opposite to the first direction,
thereby converting dislocations threading in a c-axis direction, which are contained in the original hexagonal single crystal, into defects inclined by 40° or more from the c-axis direction toward the basal plane during crystal growth, and controlling a direction of propagation of the defects to the first direction and the direction opposite to the first direction, to discharge the defects out of the crystal and near a line intermediate between the adjacent reference lines.

14. The method for producing a hexagonal single crystal according to claim 13, wherein
the main crystal growth plane has the off angle of 10° or less from the basal plane, and deflects and propagates the threading dislocations in a direction within 45° toward the first direction and the direction opposite to the first direction, thereby discharging the dislocations out of the crystal or near the intermediate line between the two adjacent reference lines.

15. The method for producing a hexagonal single crystal according to claim 13, further comprising:
setting an angle of steps at 45° or more from the basal plane in forming the cross-sectional shape which is decreased in crystal thickness in a stair-step manner from the single reference line or the plurality of reference lines orthogonal to the first direction toward the first direction and the direction opposite to the first direction.

16. The method for producing a hexagonal single crystal according to claim 13, wherein
the first direction is within ±10° from a <11-20> direction, or within ±10° from a <1-100> direction.

17. The method for producing a hexagonal single crystal according to claim 13, further comprising:
setting the reference line to be in a range of ±10 mm from a center of the single crystal in forming the cross-sectional shape which is decreased in crystal thickness in a stair-step manner from the single reference line orthogonal to the first direction toward the first direction and the direction opposite to the first direction.

18. The method for producing a hexagonal single crystal according to claim 13, further comprising:
setting one of the intermediate lines between the two adjacent reference lines to be in a range of ±10 mm from a center of the single crystal in forming the cross-sectional shape which is decreased in crystal thickness in a stair-step manner from the plurality of reference lines orthogonal to the first direction toward the first direction and the direction opposite to the first direction.

19. The method for producing a hexagonal single crystal according to claim 13, further comprising:
setting a height of steps at 2 μm or more, but 1 mm or less, a spacing between the steps at 10 μm or more, but 10 mm or less, and the number of the steps at 5 or more, in forming the cross-sectional shape which is decreased in crystal thickness in a stair-step manner from the single reference line or the plurality of reference lines orthogonal to the first direction toward the first direction and the direction opposite to the first direction.

20. A method for producing a hexagonal single crystal, comprising a process of growing a hexagonal single crystal,
the process comprising:
setting an off angle, in a first direction with respect to a basal plane serving as a main crystal growth plane, in the hexagonal single crystal for use as a foundation in performing crystal growth; and
forming a cross-sectional shape which is decreased in crystal thickness in a stair-step manner toward second directions having an angle of 30°±15° from a direction opposite to the first direction,
thereby converting dislocations threading in a c-axis direction, which are contained in the original hexagonal single crystal, into defects inclined by 40° or more from the c-axis direction toward the basal plane during crystal growth, and controlling a direction of propagation of the defects to a direction between the direction opposite to the first direction and the second directions, to discharge the defects out of the crystal.

21. The method for producing a hexagonal single crystal according to claim 20, wherein
the main crystal growth plane has the off angle of 10° or less from the basal plane, and deflects the threading dislocations in a direction within ±45° toward the first direction, thereby discharging the dislocations out of the crystal.

22. The method for producing a hexagonal single crystal according to claim 20, further comprising:
setting an angle of steps at 45° or more from the basal plane in forming the cross-sectional shape which is decreased in crystal thickness in a stair-step manner toward the second directions having the angle of 30°±15° from the direction opposite to the first direction.

23. The method for producing a hexagonal single crystal according to claim 20, wherein
the first direction is within ±10° from a <11-20> direction, or within ±10° from a <1-100> direction.

24. The method for producing a hexagonal single crystal according to claim 20, further comprising:
setting a region, where the crystal thickness becomes maximal, in a range of 10 mm or less from an end of the single crystal in forming the cross-sectional shape which is decreased in crystal thickness in a stair-step manner toward the second directions having the angle of 30°±15° from the direction opposite to the first direction.

25. The method for producing a hexagonal single crystal according to claim 20, further comprising:
setting a height of steps at 2 μm or more, but 1 mm or less, a spacing between the steps at 10 μm or more, but 10 mm or less, and the number of the steps at 5 or more, in forming the cross-sectional shape which is decreased in crystal thickness in a stair-step manner toward the second directions having the angle of 30°±15° from the direction opposite to the first direction.

26. The method for producing a hexagonal single crystal according to claim 1, further comprising:
performing the crystal growth by a chemical vapor deposition method, a sublimation method, or a solution growth method.

27. The method for producing a hexagonal single crystal according to claim 25, wherein
a temperature of the crystal growth is 1400 to 2500° C.

28. A method for producing a hexagonal single crystal wafer, comprising:
either using a hexagonal single crystal layer prepared by the method for producing a hexagonal single crystal according to claim 25, or slicing the hexagonal single crystal layer, to prepare the hexagonal single crystal wafer.

29. A method for producing a hexagonal single crystal wafer, comprising:
either using a hexagonal single crystal layer prepared by the method for producing a hexagonal single crystal according claim 25, or slicing the hexagonal single crystal layer, to prepare a hexagonal single crystal wafer; and
further either applying again the method for producing a hexagonal single crystal according to claim 25 to the hexagonal single crystal wafer, to produce a hexagonal single crystal layer having a lower threading dislocation density, and using the resulting hexagonal single crystal layer;
or slicing the hexagonal single crystal layer,
thereby preparing the hexagonal single crystal wafer.

30. A method for producing a hexagonal single crystal wafer, comprising:
either using a hexagonal single crystal layer prepared by the method for producing a hexagonal single crystal according to claim 1, or slicing the hexagonal single crystal layer, to prepare a hexagonal single crystal wafer; and
further either applying again the method for producing a hexagonal single crystal according to claim 1 to the hexagonal single crystal wafer, with the reference line being shifted by 5° or more, but 15° or less, or by 60°±10°, to produce a hexagonal single crystal layer having a lower threading dislocation density, and using the resulting hexagonal single crystal layer;
or slicing the hexagonal single crystal layer,
thereby preparing the hexagonal single crystal wafer.

31-36. (canceled)

37. The method for producing a hexagonal single crystal according to claim 1, wherein
the hexagonal single crystal is a silicon carbide single crystal.

38. The method for producing a hexagonal single crystal wafer according to claim 28, wherein
the hexagonal single crystal wafer is a silicon carbide single crystal wafer.

39-40. (canceled)
